(19) United States
(12) Patent Application Publication
(10) Pub. No.: US 2026/0198107 A1
(43) Pub. Date: Jul. 9, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Kai-Chun HSU, Tainan (TW); Yen-Yu CHEN, Kaohsiung City (TW); Zheng-Xun LI, Tainan City (TW); Bo-Ruei LIN, Tainan City (TW)

(21) Appl. No.: 19/014,692

(22) Filed: Jan. 9, 2025

(51) Int. Cl. H10F 39/18; H04N 25/77; H10F 39/00

(52) U.S. Cl. CPC H10F 39/18; H04N 25/77; H10F 39/014; H10F 39/8037; H10F 39/811

(57) ABSTRACT

A pixel sensor includes a first source-follower gate and a second-follower gate respectively connected to a photodiode and to an overflow capacitor such that the first source-follower gate may read a voltage of the photodiode, while the second source-follower gate simultaneously reads a voltage of the overflow capacitor. The arrangement including the first and second source-follower gates permits the photodiode and overflow capacitor voltages to be read at the same time, so that the time to read the photodiode and overflow capacitor voltages (e.g., read-out speed) is equal to the time during which the photodiode and overflow capacitor voltages are simultaneously read. The simultaneous reading of photodiode and overflow capacitor voltages increases an image sensor device frame rate in comparison to when the photodiode and overflow capacitor voltages are read in sequence, thereby increasing the rate at which an image sensor device captures images, and improving image sensor device performance.

### BACKGROUND

A complementary metal oxide semiconductor (CMOS) image sensor device may include a plurality of pixel sensors arranged in a pixel sensor array. A pixel sensor of the CMOS image sensor device may include a photodiode configured to convert photons of incident light to a photocurrent of electrons. The magnitude of the photocurrent is based at least in part on the intensity of the incident light.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A and 2B are diagrams of an example semiconductor device described herein.

FIGS. 2C and 2D are diagrams of portions of an example semiconductor device described herein.

FIGS. 3A-3C are diagrams of an example implementation of forming a semiconductor die (or a portion thereof) described herein.

FIGS. 4A-4D are diagrams of an example implementation of forming a semiconductor die (or a portion thereof) described herein.

FIGS. 5A and 5B are diagrams of an example implementation of forming a semiconductor device (or a portion thereof) described herein.

FIG. 6 is a diagram of a portion of an example semiconductor device described herein.

FIGS. 7A and 7B are diagrams of an example semiconductor device described herein.

FIGS. 7C and 7D are diagrams of portions of an example semiconductor device described herein.

FIGS. 8A and 8B are diagrams of an example semiconductor device described herein.

FIGS. 9A-9D are diagrams of an example implementation of forming a semiconductor die (or a portion thereof) described herein.

FIGS. 10A-10D are diagrams of an example implementation of forming a semiconductor die (or a portion thereof) described herein.

FIGS. 11A and 11B are diagrams of an example implementation of forming a semiconductor device (or a portion thereof) described herein.

FIGS. 12A and 12B are diagrams of an example semiconductor device described herein.

FIG. 12C is a diagram of portions of an example semiconductor device described herein.

FIG. 13 is a flowchart of an example process associated with forming a semiconductor device described herein.

FIG. 14 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition to a photodiode (e.g., a sensing region), a pixel sensor of an image sensor device (e.g., a complementary metal-oxide-semiconductor (CMOS) image sensor) may also include a control circuitry region. The control circuitry region is electrically connected to the photodiode and is configured to receive a photocurrent that is generated by the photodiode and to store the photocurrent in a floating diffusion node. The photocurrent in the floating diffusion node may be sampled and converted to a pixel sensor signal that can be used to generate an image and/or a video.

The pixel sensor may be a lateral overflow integration capacitor (LOFIC) pixel sensor that includes an overflow gate and an overflow capacitor. The overflow capacitor may be electrically coupled to the floating diffusion node through the overflow gate such that photocurrent may be transferred from the floating diffusion node to the overflow capacitor for temporary storage. The overflow gate may selectively control the flow of photocurrent to and/or from the overflow capacitor. This enables additional photocurrent to be transferred to the floating diffusion node from the photodiode without causing the pixel sensor to reach saturation, which increases the full well capacity (FWC) and the dynamic range of the pixel sensor.

The photocurrent may be used to apply a floating diffusion voltage to a source-follower gate of the control circuitry region. This permits the photocurrent to be observed without removing or discharging the photocurrent from the floating diffusion node. The source-follower gate functions as a high impedance amplifier for the pixel sensor. The source-follower gate provides a voltage-to-current conversion of the floating diffusion voltage. The output of the source-follower gate may be electrically connected with a row-select gate, which is configured to control the flow of the photocurrent to an image processing circuit.

In some cases, in order to process an image, the source-follower gate may read a voltage from the photodiode and a voltage from the overflow capacitor. However, where the overflow capacitor and the photodiode are coupled to a common source-follower gate through the floating diffusion node, the source-follower gate may read the photodiode and overflow capacitor voltages in sequence. As a result, the time to read photodiode and overflow capacitor voltages (e.g., read-out speed) is equal to the sum of the time to read the photodiode voltage (t1) and the time to read the overflow capacitor voltage (t2). The frame rate of an image sensor device, which is the number of images an image sensor device can capture per second (e.g., frames per second (FPS)), is directly proportional to read-out speed. As a result, the sequential reading of photodiode and overflow capacitor voltages limits image sensor device frame rate.

In some implementations described herein, a pixel sensor includes a first source-follower gate and a second-follower gate respectively connected to a photodiode and to an overflow capacitor such that the first source-follower gate may read a voltage of the photodiode, while the second source-follower gate simultaneously reads a voltage of the overflow capacitor. The arrangement including the first and second source-follower gates permits the photodiode and overflow capacitor voltages to be read at the same time, so that the time to read the photodiode and overflow capacitor voltages (e.g., read-out speed) is equal to the time during which the photodiode and overflow capacitor voltages are simultaneously read. The simultaneous reading of photodiode and overflow capacitor voltages increases an image sensor device frame rate in comparison to when the photodiode and overflow capacitor voltages are read in sequence, thereby increasing the rate at which an image sensor device captures images, and improving image sensor device performance.

The first and second source-follower gates and other components of a pixel sensor may be distributed across multiple semiconductor dies (e.g., two or more semiconductor dies) of a three-dimensional (3D) stacked CMOS image sensor (3D CIS) device. As a result, a sensing area (e.g., a photodiode) of the pixel sensor may be increased by including the sensing area on a different semiconductor die than other components of the pixel sensor, so that the overall size of the pixel sensor may be reduced while maintaining (or even increasing) the size of the sensing area. Accordingly, the multiple-semiconductor-die distribution of the components of the pixel sensor enables a high FWC to be achieved for the pixel sensor.

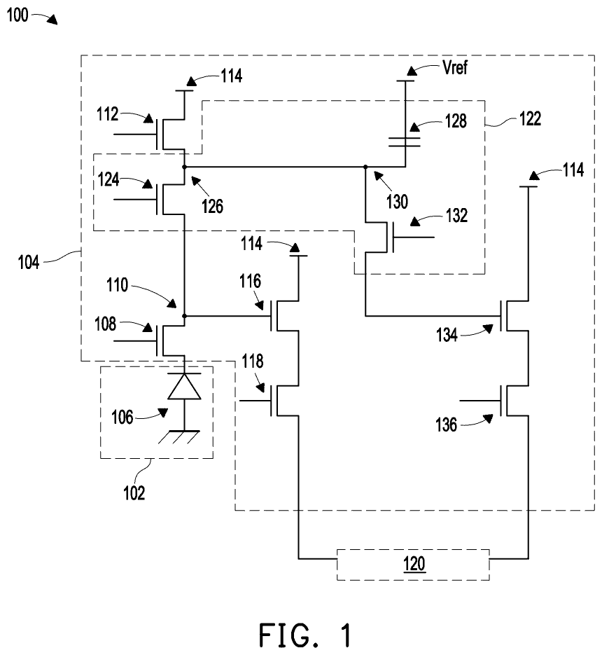

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

The pixel sensor 100 includes a sensing region 102 that may be configured to sense and/or accumulate incident light (e.g., light directed toward the pixel sensor 100). The pixel sensor 100 also includes a control circuitry region 104. The control circuitry region 104 is electrically connected with the sensing region 102 and is configured to receive a photocurrent that is generated by the sensing region 102. Moreover, the control circuitry region 104 is configured to transfer the photocurrent from the sensing region 102 to downstream circuits such as image processing circuits, among other examples.

The sensing region 102 includes a photodiode 106. The photodiode 106 may absorb and accumulate photons of the incident light, and may generate the photocurrent based on absorbed photons. The magnitude of the photocurrent is based on the amount of light collected in the photodiode 106. Thus, the accumulation of photons in the photodiode 106 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 106 is electrically connected with a source/drain of a transfer gate 108 of the control circuitry region 104. The transfer gate 108 is configured to control the transfer of the photocurrent from the photodiode 106 to a floating diffusion node 110. The photocurrent is provided from a source/drain (e.g., which may correspond to the photodiode 106) of the transfer gate 108 to another drain/drain of the transfer gate 108 (e.g., which may correspond to the floating diffusion node 110) based on selectively switching a gate of the transfer gate 108. The gate of the transfer gate 108 may be selectively switched by applying a transfer voltage (Vₜₓ) to the transfer gate 108. In some implementations, the transfer voltage being applied to the transfer gate 108 causes a conductive channel (e.g., a leakage path or buried channel) to form between the photodiode 106 and the floating diffusion node 110, which enables the photocurrent to propagate through the conductive channel from the photodiode 106 to the floating diffusion node 110. In some implementations, the transfer voltage being removed from the transfer gate 108 (or the absence of the transfer voltage) causes the conductive channel to be removed such that the photocurrent cannot pass from the photodiode 106 to the floating diffusion node 110.

The control circuitry region 104 further includes a reset transistor 112. The reset transistor 112 is electrically connected to a supply voltage source 114. The reset transistor 112 may be controlled by a reset voltage (Vᵣₛₜ) applied by the supply voltage source 114. The reset transistor 112 may be electrically coupled with the floating diffusion node 110. The reset voltage may be applied to the reset transistor 112 to pull the floating diffusion node 110 to a high voltage (e.g., to the supply voltage) to “reset” the floating diffusion node 110 (e.g., by draining any residual charge in the floating diffusion node 110) prior to activation of the transfer gate 108 to transfer the photocurrent from the photodiode 106 to the floating diffusion node 110.

The photocurrent may be used to apply a floating diffusion voltage (V_{fd}) to a first source-follower gate 116 of the control circuitry region 104. This permits the photocurrent to be observed without removing or discharging the photocurrent from the floating diffusion node 110. The reset transistor 112 may instead be used to remove or discharge the photocurrent from the floating diffusion node 110.

The first source-follower gate 116 functions as a first high impedance amplifier for the pixel sensor 100. The first source-follower gate 116 provides a voltage to current conversion of the floating diffusion voltage. The output of the first source-follower gate 116 is electrically connected with a first row-select gate 118, which is configured to control the flow of a first photocurrent to an image processing circuit 120. The first row-select gate 118 is controlled by selectively applying a select voltage (V_{di}) to the gate of the first row-select gate 118. This permits the first photocurrent to flow to an output of the pixel sensor 100. The image processing circuit 120 may be a part of the pixel sensor 100 or may be a separate part of a semiconductor device in which the pixel sensor 100 and the image processing circuit 120 are included.

As further shown in FIG. 1, the control circuitry region 104 of the pixel sensor 100 includes a conversion gain circuit 122. The conversion gain circuit 122 can be selectively activated or deactivated to enable a sequential conversion gain operation to be performed for an exposure operation of the pixel sensor 100 (e.g., an exposure operation to generate an image and/or a video). The conversion gain circuit 122 enables the capacitance of the pixel sensor 100 to be gradually increased through the exposure operation, which gradually increases the FWC of the pixel sensor 100. The increased capacitance enables additional charge to be stored in the control circuitry region 104 during the exposure operation, which enables the level of the photocurrent to be increased during the exposure operation. In this way, the conversion gain can be inversely decreased so that a high dynamic range can be achieved in the exposure operation.

The conversion gain circuit 122 includes a first conversion gain transistor 124, a first junction 126 between source/drain terminals (e.g. source/drain regions) of the first conversion gain transistor 124 and the reset transistor 112, a capacitor 128, a second junction 130, and a second conversion gain transistor 132. The second junction 130 is between the capacitor 128 and a source/drain terminal of the second conversion gain transistor 132.. A first source/drain terminal of the first conversion gain transistor 124 is electrically coupled to the floating diffusion node 110, and a second source/drain terminal of the first conversion gain transistor 124 is electrically coupled to the capacitor 128. The capacitor 128 is electrically coupled to a reference voltage source (Vref). The capacitor 128 is electrically coupled to the floating diffusion node 110 through the first conversion gain transistor 124.

A first source/drain terminal of the second conversion gain transistor 132 is electrically coupled to the capacitor 128, and a second source/drain terminal of the second conversion gain transistor 132 is electrically coupled to a second source-follower gate 134, such that the second conversion gain transistor 132 is coupled between the capacitor 128 and the second source-follower gate 134.

In some implementations, Vref may be the same as the supply voltage source 114. In some implementations, Vref may be different from the supply voltage source 114.

The first conversion gain transistor 124 enables the conversion gain circuit 122 to be selectively activated or deactivated. For example, when the first conversion gain transistor 124 is activated, the capacitor 128 may be connected to the floating diffusion node 110, thereby enabling the capacitor 128 to function as an LOFIC for the floating diffusion node 110. In particular, the capacitor 128 may store overflow charge from the floating diffusion node 110, thereby enabling additional charge generated by the photodiode 106 to be stored in the floating diffusion node 110 without the floating diffusion node 110 reaching saturation. In addition, during an integration (e.g., exposure) time, when the first conversion gain transistor 124 is activated and the capacitor 128 is connected to the floating diffusion node 110 to be charged with voltage from the floating diffusion node 110, the second conversion gain transistor 132 is deactivated. When the first conversion gain transistor 124 is deactivated, the capacitor 128 may be disconnected from the floating diffusion node 110.

The capacitor 128 and the reset transistor 112 may be electrically coupled to the second source/drain terminal of the first conversion gain transistor 124 and to the supply voltage source 114 in parallel. The floating diffusion node 110 may be reset by activating the first conversion gain transistor 124 and the reset transistor 112.

As noted above, the first source-follower gate 116 functions as a first high impedance amplifier for the pixel sensor 100, and provides a voltage-to-current conversion of the floating diffusion voltage from the photodiode 106. The second source-follower gate 134 functions as a second high impedance amplifier for the pixel sensor 100, and provides a voltage-to-current conversion of the stored voltage from the capacitor 128. The output of the second source-follower gate 134 is electrically connected with the second row-select gate 136, which is configured to control the flow of a second photocurrent to the image processing circuit 120. The second row-select gate 136 is controlled by selectively applying a select voltage (V_{di}) to the gate of the second row-select gate 136. This permits the second photocurrent to flow to an output of the pixel sensor 100.

The first source-follower gate 116 and the second-follower gate 134 are respectively connected to the photodiode 106 and to capacitor 128 such that the first source-follower gate 116 may read a voltage of the photodiode 106, while the second source-follower gate 134 simultaneously reads a voltage of the capacitor 128. The arrangement including the first source-follower gate 116 and the second source-follower gate 134 permits the photodiode and capacitor voltages to be read at the same time, so that the time to read the photodiode and capacitor voltages (e.g., read-out speed) is equal to or substantially equal to the time during which the photodiode and overflow capacitor voltages are simultaneously read. The simultaneous reading of voltages of the photodiode 106 and capacitor 128 increases a frame rate of an image sensor device including the pixel sensor 100 in comparison to when the photodiode and overflow capacitor voltages are read in sequence, thereby increasing the rate at which the image sensor device captures images, and improving image sensor device performance.

As noted above, the first conversion gain transistor 124 is activated during an integration time to charge the capacitor 128. The first conversion gain transistor 124 is deactivated when the first source-follower gate 116 reads the voltage of the photodiode 106, and the second source-follower gate 134 simultaneously reads the voltage of the charged capacitor 128. During the integration time to charge the capacitor 128, the second conversion gain transistor 132 is deactivated to prevent current flow from the floating diffusion node 110 from reaching the second source-follower gate 134 through the second conversion gain transistor 132. The second conversion gain transistor 132 is activated when the first source-follower gate 116 reads the voltage of the photodiode 106, so that voltage of the capacitor 128 can flow through the second conversion gain transistor 132 to the second source-follower gate 134. As a result, the second source-follower gate 134 can read the voltage of the capacitor 128 at the same time that the first source-follower gate 116 reads the voltage of the photodiode 106.

The outputs of the first source-follower gate 116 and the second source-follower gate 134 can be simultaneously sent to the image processing circuit 120 by selectively applying the select voltage (V_{di}) to the gates of the first row-select gate 118 and the second row-select gate 136, so that the first and second photocurrents may flow to one or more outputs of the pixel sensor 100 to the image processing circuit 120.

As indicated above, FIG. 1 is provided as an example. Other examples may differ from what is described with regard to FIG. 1.

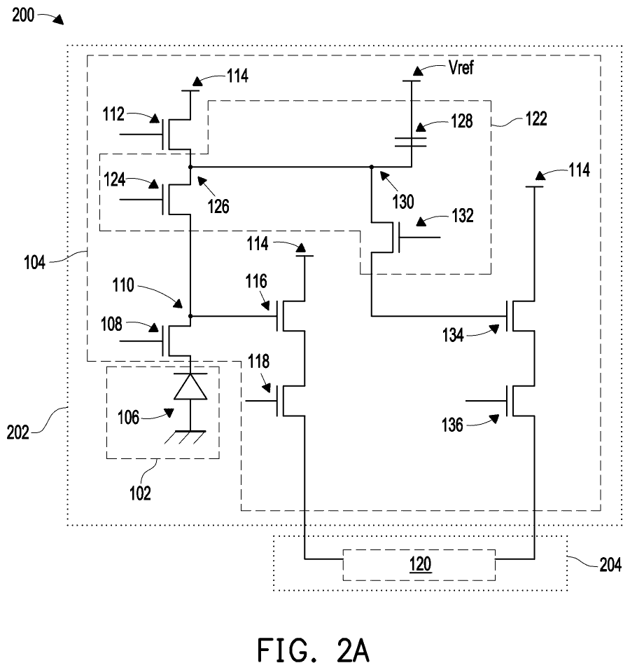

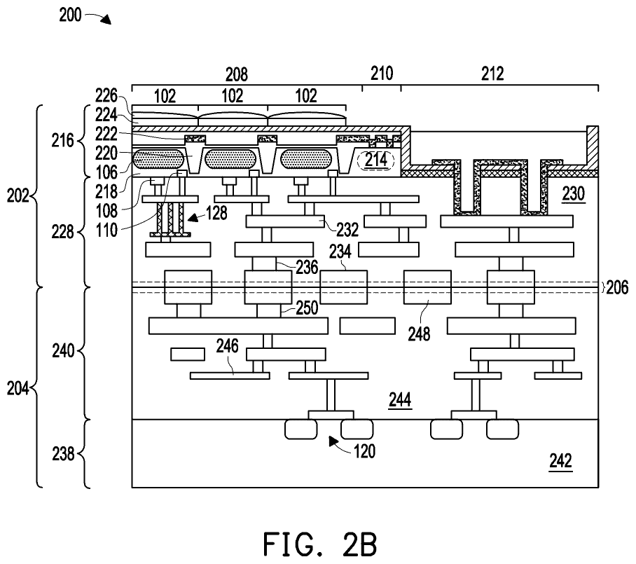

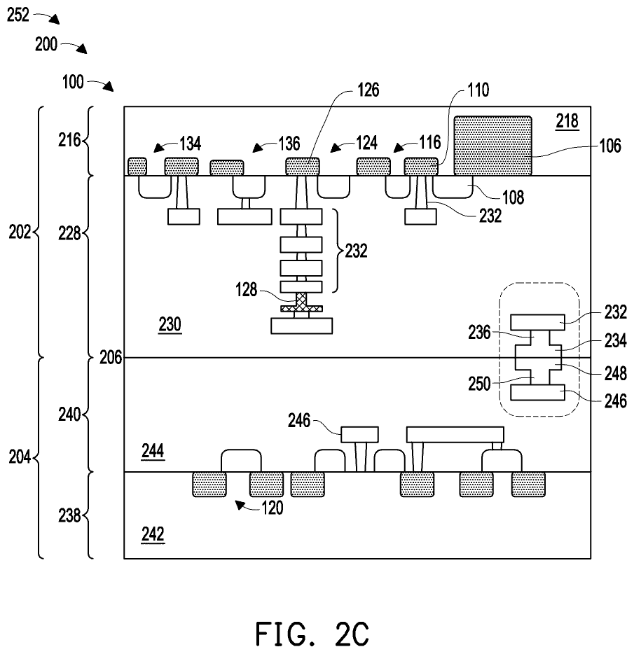

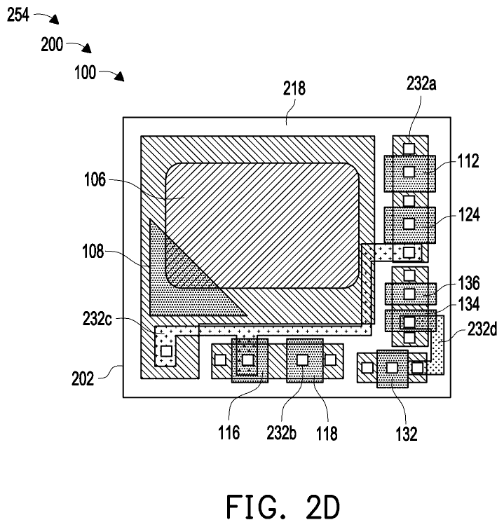

FIGS. 2A and 2B are diagrams of an example semiconductor device 200 described herein. The semiconductor device 200 includes an image sensor device such as a CMOS image sensor device that includes one or more pixel sensors 100. FIG. 2A illustrates an example distribution of components across a plurality of semiconductor dies of the semiconductor device 200. FIG. 2B illustrates a cross-sectional view of a structural implementation of the semiconductor device 200.

As shown in FIG. 2A, the pixel sensor 100, including the sensing region 102 and the control circuitry region 104, may be included on a semiconductor die 202. The semiconductor die 202 may be an image sensor die of the semiconductor device 200. The image processing circuit 120 may be included on a semiconductor die 204. The semiconductor die 204 may be an image sensor processing (ISP) die and/or an application-specific integrated circuit (ASIC) die.

As shown in FIG. 2B, the semiconductor dies 202 and 204 may be vertically stacked or vertically arranged in the semiconductor device 200. The semiconductor die 202 and the semiconductor die 204 may be bonded at a bonding interface 206. Thus, the semiconductor device 200 may be a 3D CIS because of the vertical arrangement of the semiconductor dies 202 and 204. The bond between the semiconductor dies 202 and 204 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 202 and 204 by forming metal-to-metal bonds and/or dielectric-to-dielectric bonds at the bonding interface 206 between the semiconductor dies 202 and 204.

The semiconductor die 202 may include a pixel sensor array 208, a black level correction (BLC) region 210 adjacent to (e.g., horizontally adjacent to) the pixel sensor array 208, and a bonding pad region 212 adjacent to (e.g., horizontally adjacent to) the BLC region 210, among other examples. In some implementations, the semiconductor die 202 includes additional lateral regions, such as a seal ring region and/or a scribe line region, among other examples.

The pixel sensor array 208 includes a plurality of sensing regions 102 of a plurality of pixel sensors 100. The sensing regions 102 of the pixel sensors 100 may be arranged in a grid or in another type of arrangement, and may be configured to generate photocurrents based on photons of incident light. The BLC region 210 may include a region 214 in a device layer 216 of the semiconductor die 202 that is shielded from incident light by a metal shielding layer. The metal shielding layer may be included as a light-blocking layer to prevent incident light from entering the region 214. The region 214 is thus a sensing region that is kept “dark” so that dark current measurements may be performed in the BLC region 210. A dark current measurement may be performed to measure the amount of charge (dark current) in the device layer 216 that is generated from sources other than incident light (e.g., from thermal energy in the device layer 216) so that the dark current measurement may be used for black level correction (or black level calibration) for the pixel sensor array 208. The bonding pad region 212 may include a bonding pad structure that enables an external electrical connection to be formed with the semiconductor device 200.

The device layer 216 includes a substrate layer 218. The substrate layer 218 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, or another type of semiconductor material.

Photodiodes 106 of the sensing regions 102 of the pixel sensors 100 are included in the substrate layer 218 of the semiconductor die 202. The photodiodes 106 may each include one or more doped regions of substrate layer 218. The substrate layer 218 may be doped with a plurality of types of ions to form a p-n junction or a PIN junction (e.g., a junction between a p-type portion, an intrinsic (or undoped) type portion, and an n-type portion) corresponding to a photodiode 106. For example, the substrate layer 218 may be doped with an n-type dopant to form a first portion (e.g., an n-type portion) of a photodiode 106 and a p-type dopant to form a second portion (e.g., a p-type portion) of the photodiode 106. A photodiode 106 may be configured to absorb photons of incident light. The absorption of photons causes the photodiode 106 to accumulate a charge (a photocurrent) due to the photoelectric effect. Here, photons bombard the photodiode 106, which causes emission of electrons of the photodiode 106. The emission of electrons causes the formation of electron-hole pairs, where the electrons migrate toward the cathode of the photodiode 106 and the holes migrate toward the anode, which produces the photocurrent.

The photodiodes 106 may be electrically isolated and/or optically isolated from one another by one or more isolation structures in the substrate layer 218. For example, a deep trench isolation (DTI) structure 220 may extend into the substrate layer 218 from a back side of the substrate layer 218. The DTI structure 220 may include elongated structures that include one or more dielectric layers, one or more metal layers, and/or another arrangement of layers and/or materials. The DTI structure 220 may laterally surround the photodiodes 106 of the pixel sensors 100 in the substrate layer 218.

A grid structure 222 may be included above the back side of the substrate layer 218. Sections of the grid structure 222 may be located over the DTI structure 220 and may be formed around the perimeter of the photodiodes 106 of the sensing regions 102 of the pixel sensors 100. Openings in the grid structure 222 are included above the photodiodes 106 to enable incident light to pass through the grid structure 222 and to the photodiodes 106. In some implementations, the grid structure 222 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples. In some implementations, the grid structure 222 may be formed of a dielectric material. In some implementations, the grid structure 222 is a multi-layer structure that includes one or more metal layers and/or one or more dielectric layers that are vertically stacked.

Color filter regions 224 of the sensing regions 102 of the pixel sensors 100 may be included in the openings in the grid structure 222. The color filter regions 224 may be included above the photodiodes 106 of the sensing regions 102 of the pixel sensors 100. The color filter regions 224 may be included above the photodiodes 106. Each color filter region 224 may be configured to filter incident light to allow a particular wavelength of the incident light to pass to a photodiode 106. For example, a color filter region 224 may filter incident light to allow red light to pass through the color filter region 224 to an associated photodiode 106. As another example, a color filter region 224 may filter incident light to allow green light to pass through the color filter region 224 to an associated photodiode 106. As another example, a color filter region 224 may filter incident light to allow blue light to pass through the color filter region 224 to an associated photodiode 106. In some implementations, a color filter region 224 may be non-discriminating or non-filtering, which may define a white pixel sensor. A non-discriminating or non-filtering color filter region 224 may include a material that permits all wavelengths of light to pass into the associated photodiode 106 (e.g., for purposes of determining overall brightness to increase light sensitivity for the image sensor). In some implementations, a color filter region 224 may be a near infrared (NIR) bandpass color filter region 224, which may define an NIR pixel sensor. An NIR bandpass color filter region 224 may include a material that permits the portion of incident light in an NIR wavelength range to pass to an associated photodiode 106 while blocking visible light from passing.

Micro-lenses 226 may be included over and/or on the color filter regions 224. The micro-lenses 226 may include a respective micro-lens for each of the sensing regions 102 of the pixel sensors 100. A micro-lens 226 may be formed to focus incident light toward a photodiode 106 of a sensing region 102 of a pixel sensor 100.

Transfer gates 108 of the pixel sensors 100 are included on the front side of the substrate layer 218. The transfer gates 108 are configured to selectively control the flow of photocurrents from the photodiodes 106 to floating diffusion nodes 110 of the pixel sensors 100. The floating diffusion nodes 110 may also be included in the substrate layer 218. A transfer gate 108 may selectively control the flow of a photocurrent from a photodiode 106 of a pixel sensor 100 to a floating diffusion node 110 of the pixel sensor 100 by selectively controlling a leakage path (e.g., a buried channel) between the photodiode 106 and the floating diffusion node 110 in the substrate layer 218. When a gate voltage (e.g., a transfer voltage (Vₜₓ)) is applied to the transfer gate 108, the leakage path may be formed in the substrate layer 218, thereby enabling a photocurrent to flow from the photodiode 106 to the floating diffusion node 110. When the gate voltage is removed, the leakage path is closed, thereby preventing the photocurrent from floating from the photodiode 106 to the floating diffusion node 110.

Not shown in FIG. 2B are additional components of the control circuitry regions 104 of the pixel sensors 100 that may be included in the substrate layer 218. Such components may include, for example, the reset transistors 112, the first source-follower gates 116, the first row-select gates 118, the first conversion gain transistors 124 and the second conversion gain transistors 132 of conversion gain circuits 122, the second source-follower gates 134, and/or the second source-follower gates 136, among other examples.

The semiconductor die 202 may include an interconnect layer 228 vertically adjacent to the device layer 216. The interconnect layer 228 may include a dielectric region 230 that includes one or more dielectric layers. The dielectric layers may include backend dielectric layers (e.g., interlayer dielectric (ILD) layers, intermetal dielectric (IMD) layers) and etch stop layers (ESLs) that are arranged in a direction that is approximately orthogonal to the substrate layer 218. The dielectric regions 230 may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 228 may further include a plurality of conductive structures 232 (e.g., electrically conductive structures) in the dielectric region 230. The conductive structures 232 are electrically coupled and/or physically coupled to the transfer gates 108, the floating diffusion nodes 110, and/or other structures of the pixel sensors 100 in the device layer 216. Moreover, the conductive structures 232 may be electrically interconnected together in the interconnect layer 228. The conductive structures 232 correspond to circuit routing that enables signals and/or power to be provided to and/or from components of the pixel sensors 100 in the device layer 216. The conductive structures 232 may include a combination of conductive structures that extend primarily horizontally in the interconnect layer 228 (e.g., trenches, conductive lines) and that are interconnected by interconnect structures (e.g., vias) that extend primarily vertically in the interconnect layer 228. The conductive structures 232 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 228 may be arranged in a vertical manner to facilitate electrical signals and/or power to be routed between the device layer 216 and the semiconductor die 204, between integrated circuit devices in the device layer 216 through the interconnect layer 228, and/or between the integrated circuit devices in the device layer 216 and integrated circuit devices in the semiconductor die 204. The conductive structures 232 may be arranged in alternating layers of metallization layers (referred to as “M”-layers) and via layers (referred to as “V” layers). Each metallization layer may include one or more conductive structures laterally arranged in the interconnect layer 228, and each via layer may include one or more interconnect structures that interconnect the metallization layers in the interconnect layer 228. As an example, a metal-0 (M0) layer may be located at the bottom of the interconnect layer 228 and may be coupled to the integrated circuit devices (e.g., the transfer gates 108, the floating diffusion nodes 110) in the device layer 216, a via-0 (V0) layer may be located above and coupled to the M0 layer in the interconnect layer 228, a metal-1 (M1) layer may be located above and coupled to the V0 layer in the interconnect layer 228, a via-1 (V1) layer may be located above and coupled to the M1 layer in the interconnect layer 228, a metal-2 (M2) layer may be located above and electrically coupled to the V1 layer in the interconnect layer 228, and so on. In some implementations, the interconnect layer 228 includes nine (9) stacked metallization layers (e.g., M0-M8). In other implementations, the contact layer (referred to as “CO”-layer) may be located at the bottom of the interconnect layer 228 and may be directly coupled to the integrated circuit devices (e.g., with the transfer gates 108, with the floating diffusion nodes 110) in the device layer 216, a metal-1 (M1) layer may be located above and coupled to the CO layer in the interconnect layer 228, and so on. In some implementations, the interconnect layer 228 includes another quantity of stacked metallization layers.

The capacitors 128 of the conversion gain circuits 122 of the pixel sensors 100 may be included in the interconnect layer 228 of the semiconductor die 202. Additionally and/or alternatively, one or more of the capacitors 128 may be included in the device layer 216 (e.g., in the substrate layer 218) of the semiconductor die 202.

The capacitors 128 may be electrically coupled to the floating diffusion nodes 110 of the pixel sensors 100 through one or more conductive structures 232 in the interconnect layer 228. The capacitors 128 may be implemented as various types of capacitor structures, such as planar capacitor structures, trench capacitor structures, deep trench capacitor (DTC) structures, and/or other types of capacitor structures.

At the bonding interface 206 between the semiconductor dies 202 and 204, the interconnect layer 228 may include a plurality of bonding pads 234. The bonding pads 234 may be electrically coupled to the conductive structures 232 in the interconnect layer 228 by bonding vias 236 and/or other types of conductive structures. The bonding pads 234 and the bonding vias 236 may each include tungsten (W), cobalt (Co), ruthenium (Ru), titanium (Ti), aluminum (Al), copper (Cu), gold (Au), and/or a combination thereof, among other examples of electrically conductive metals.

The semiconductor die 204 may include one or more components of the image processing circuits 120 coupled to the pixel sensors 100 of the semiconductor device 200. The semiconductor die 204 may include a device layer 238 and an interconnect layer 240 vertically adjacent to the device layer 238. The device layer 238 may include a substrate layer 242, and one or more components of the image processing circuits 120 may be included in and/or on the substrate layer 242. The substrate layer 242 may include a silicon (Si) substrate, an SOI substrate, and/or another type of substrate. The image processing circuits 120 may include integrated circuit devices such as transistor structures (e.g., planar transistors, fin field effect transistors (finFETs), nanostructure transistors (e.g., nanosheet transistors, gate all around (GAA) transistors), capacitor structures, resistor structures, inductor structures, and/or other types of semiconductor structures).

The interconnect layer 240 may include a similar combination and/or arrangement of structures and/or layers as the interconnect layer 228 of the semiconductor die 202. For example, the interconnect layer 240 may include a dielectric region 244 (similar to the dielectric region 230) and a combination of conductive structures 246 (similar to the conductive structures 232) in the dielectric region 244. Moreover, the interconnect layer 240 may include bonding pads 248 that are electrically coupled to one or more of the conductive structures 246 by bonding vias 250. These layers and/or structures may have a reversed vertical arrangement relative to the semiconductor die 202, which enables the semiconductor die 202 and the semiconductor die 204 to be bonded at the bonding interface 206 such that the interconnect layer 228 and the interconnect layer 240 are facing each other and bonded together.

At the bonding interface 206, the bonding pads 234 of the semiconductor die 204 and bonding pads 248 of the semiconductor die 204 are directly bonded by metal-to-metal bonds. Moreover, the dielectric region 230 of the semiconductor die 202 and the dielectric region 244 of the semiconductor die 204 are directly bonded by dielectric-to-dielectric bonds.

FIG. 2C illustrates a cross-sectional view of a structural implementation 252 of the semiconductor device 200. As shown in FIG. 2C, the semiconductor dies 202 and 204 may be vertically stacked or vertically arranged in the semiconductor device 200. The semiconductor die 202 and the semiconductor die 204 may be bonded at a bonding interface 206 through bonding pads 234 and 248. In the structural implementation 252, a photodiode 106 of the sensing region 102 of a pixel sensor 100 is included in the substrate layer 218 of the semiconductor die 202. The substrate layer 218 further includes source/drain regions of the transfer gate 108, of the first source-follower gate 116, of the first conversion gain transistor 124, of the second source-follower gate 134, and of the second row-select gate 136. The first junction 126 is further illustrated in the substrate layer 218. The floating diffusion node 110 may be a source/drain region of the transfer gate 108. The first source-follower gate 116, the second source-follower gate 134, the second row-select gate 136, the transfer gate 108, and a gate of the first conversion gain transistor 124 are formed on the substrate layer 218.

Not shown in FIG. 2C are additional components of the control circuitry region 104 of a pixel sensor 100 that may be included in the substrate layer 218. Such components may include, for example, the reset transistor 112, and the second conversion gain transistor 132 of conversion gain circuit 122, among other examples.

The dielectric region 230 of the interconnect layer 228 may include a plurality of conductive structures 232 (e.g., electrically conductive structures) in the dielectric region 230. The conductive structures 232 are electrically coupled and/or physically coupled to the source/drain regions of the transfer gate 108, of the first source-follower gate 116, of the first conversion gain transistor 124, of the second source-follower gate 134, and/or of the second row-select gate 136. The conductive structures 232 may also be electrically coupled to the transfer gate 108, the floating diffusion node 110, the first source-follower gate 116, the first conversion gain transistor 124, the capacitor 128, the first junction 126, the second source-follower gate 134, the second row-select gate 136, and/or other structures of the pixel sensor 100 in the device layer 216. The conductive structures 232 may be electrically interconnected together in the interconnect layer 228. The capacitor 128 may be electrically coupled to the first junction 126 through one or more conductive structures 232 in the interconnect layer 228.

The bonding interface 206 between the semiconductor dies 202 and 204 may include a plurality of bonding pads 234 in the dielectric region 230. The bonding pads 234 may be electrically coupled to the conductive structures 232 in the interconnect layer 228 by bonding vias 236 and/or other types of conductive structures.

The semiconductor die 204 may include one or more components of the image processing circuit 120, such as one or more transistors, coupled to the pixel sensor 100 of the semiconductor device 200. The semiconductor die 204 may include a device layer 238 and an interconnect layer 240 vertically adjacent to the device layer 238. The device layer 238 may include a substrate layer 242, and the one or more components of the image processing circuit 120 may be included in and/or on the substrate layer 242.

The interconnect layer 240 may include a similar combination and/or arrangement of structures and/or layers as the interconnect layer 228 of the semiconductor die 202. For example, the interconnect layer 240 may include a dielectric region 244 (similar to the dielectric region 230) and a combination of conductive structures 246 (similar to the conductive structures 232) in the dielectric region 244. Moreover, the interconnect layer 240 may include bonding pads 248 that are electrically coupled to one or more of the conductive structures 246 by bonding vias 250.

FIG. 2D is a diagram of an example implementation 254 of a portion of the semiconductor device 200 described herein. In the example implementation 254, FIG. 2D is a top view of a portion of the semiconductor device 200 including the photodiode 106, the transfer gate 108, the reset transistor 112, the first source-follower gate 116, the first row-select gate 118 adjacent to the first source-follower gate 116, the first conversion gain transistor 124 adjacent to the reset transistor 112, the second conversion gain transistor 132, the second source-follower gate 134, and the second row-select gate 136 adjacent to the second source-follower gate 134. The substrate layer 218 includes source/drain regions corresponding to adjacent gates of a given transistor. The conductive structures 232a and 232b respectively contacting the source/drain regions and gates respectively correspond to source/drain interconnects and gate interconnects. A conductive structure 232c connects a source/drain region of the first conversion gain transistor 124 with a source/drain region of the transfer gate 108 and with the first source-follower gate 116. The conductive structures 232a, 232b, and/or 232c may include a combination of conductive structures that extend primarily horizontally in the interconnect layer 228 (e.g., trenches, conductive lines) and that are interconnected by interconnect structures (e.g., vias) that extend primarily vertically in the interconnect layer 228.

As indicated above, FIGS. 2A-2D are provided as an example. Other examples may differ from what is described with regard to FIGS. 2A-2D.

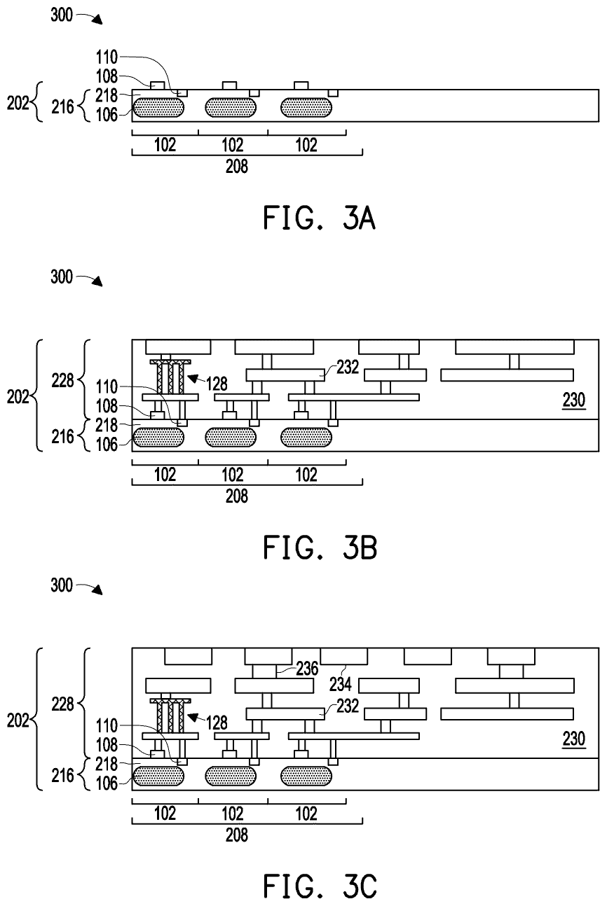

FIGS. 3A-3C are diagrams of an example implementation 300 of forming the semiconductor die 202 (or a portion thereof) described herein. In some implementations, one or more of the semiconductor processing operations described in connection with FIGS. 3A-3C may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 3A, the substrate layer 218 of the device layer 216 of the semiconductor die 202 is provided. The substrate layer 218 may be provided in the form of a semiconductor wafer such as a silicon (Si) wafer may be provided as an SOI wafer, and/or another type of semiconductor work piece.

As further shown in FIG. 3A, photodiodes 106 of the sensing regions 102 of the pixel sensors 100 of the pixel sensor array 208 may be formed in the substrate layer 218 of the semiconductor die 202. The photodiodes 106 may be formed from the front side of the substrate layer 218. In some implementations, an ion implantation tool may be used to implant ions into the substrate layer 218 to form a P-N junction between a p-doped region of the substrate layer 218 and an n-doped region of the substrate layer 218, or to form a P-I-N junction between p-doped region of the substrate layer 218, an n-doped region of the substrate layer 218, and an intrinsic (e.g., undoped) semiconductor region for a photodiode 106.

As further shown in FIG. 3A, additional regions of the substrate layer 218 may be doped to form the floating diffusion nodes 110. Transfer gates 108 of the pixel sensors 100 may be formed over and/or on the front side surface of the substrate layer 218. Forming transfer gates 108 may include depositing a gate dielectric on the front side surface of the substrate layer 218, depositing a gate electrode on the gate dielectric layer, and/or forming sidewall spacers on sidewalls of the gate electrode, among other examples. Additional structures of the control circuitry regions 104 of the pixel sensors may be formed in and/or on the substrate layer 218 in a similar manner. Such additional structures may include the reset transistors 112, the first source-follower gates 116, the first row-select gates 118, the first conversion gain transistors 124 and the second conversion gain transistors 132 of conversion gain circuits 122, the second source-follower gates 134, and/or the second row-select gates 136, among other examples. The reset transistors 112, the first source-follower gates 116, the first row-select gates 118, the first conversion gain transistors 124 and the second conversion gain transistors 132 of conversion gain circuits 122, the second source-follower gates 134, and/or the second row-select gates 136 may be implemented as various types of transistor structures, including planar transistors, finFETs, and/or nanostructure transistors, among other examples.

As shown in FIG. 3B, the dielectric region 230 of the interconnect layer 228 of the semiconductor die 202 may be formed over the front side of the substrate layer 218. The conductive structures 232 may be formed in the dielectric region 230.

A deposition tool may be used to deposit the dielectric region 230 using a physical vapor deposition (PVD) technique, an atomic layer deposition (ALD) technique, a chemical vapor deposition (CVD) technique, an oxidation technique, and/or another suitable deposition technique. The dielectric region 230 may be deposited as one or more dielectric layers. In some implementations, a planarization tool may be used to perform a planarization operation (e.g., a chemical mechanical planarization (CMP) operation) to planarize the one or more layers of the dielectric region 230 after the one or more layers of the dielectric region 230 are deposited.

A deposition tool may be used to deposit the conductive structures 232 using a PVD technique, a CVD technique, an ALD technique, an electroplating technique, and/or another suitable deposition technique. In some implementations, a seed layer may be deposited, and a conductive structure 232 may be deposited on the seed layer. In some implementations, a liner may be deposited, and a conductive structure 232 may be deposited on the liner. The liner may include a barrier liner, a diffusion liner, an adhesion liner, and/or another type of liner. Examples of such liners may include a tantalum nitride (TaN) liner and/or a titanium nitride (TiN) liner, among other examples.

One or more semiconductor processing tools may be used to form the interconnect layer 228 by forming one or more dielectric layers of the dielectric region 230 and forming a plurality of conductive structures 232 in the dielectric layer(s) of the dielectric region 230. For example, a deposition tool may be used to deposit a first dielectric layer of the dielectric region 230, an etch tool may be used to remove portions of the first dielectric layer to form recesses in the first dielectric layer, and a deposition tool may be used to form a first layer (e.g., a via layer, a metallization layer) of one or more conductive structures 232 in the recesses. At least a portion of the first layer of conductive structures 232 may be electrically connected and/or physically connected with the transfer gates 108 and/or with the floating diffusion nodes 110 (e.g., and/or other components of the pixel sensors 100). Similar processing operations may be performed to form additional layers of the interconnect layer 228 until a sufficient or desired arrangement of conductive structures 232 is achieved.

As further shown in FIG. 3B, the capacitors 128 may be formed above the front side of the substrate layer 218 in the interconnect layer 228. In some implementations, a capacitor 128 is formed by depositing a metal-insulator-metal (MIM) layer stack, and etching the MIM layer stack to define a planar capacitor structure. In some implementations, in these examples, a capacitor 128 is formed by forming a trench in the dielectric region 230 and forming the MIM layer stack in the trench to define a trench capacitor structure or DTC structure. Additionally and/or alternatively, one or more of the capacitors 128 may be formed in the substrate layer 218.

As shown in FIG. 3C, the bonding vias 236 may be formed on one or more conductive structures 232 in the interconnect layer 228, and bonding pads 234 may be formed above the bonding vias 236. In some implementations, one or more bonding pads 234 are formed on one or more bonding vias 236.

A deposition tool may be used to deposit the bonding pads 234 and/or the bonding vias 236 using a PVD technique, a CVD technique, an ALD technique, an electroplating technique, and/or another suitable deposition technique. In some implementations, a seed layer may be deposited, and a bonding pad 234 or a bonding via 236 may be deposited on the seed layer. In some implementations, a liner may be deposited, and a bonding pad 234 or a bonding via 236 may be deposited on the liner. The liner may include a barrier liner, a diffusion liner, and adhesion liner, and/or another type of liner. Examples of such liners may include a tantalum nitride (TaN) liner and/or a titanium nitride (TiN) liner, among other examples. In some implementations, a planarization tool may be used to perform a planarization operation (e.g., a CMP operation) to planarize a bonding pad 234 or a bonding via 236.

As indicated above, FIGS. 3A-3C are provided as an example. Other examples may differ from what is described with regard to FIGS. 3A-3C.

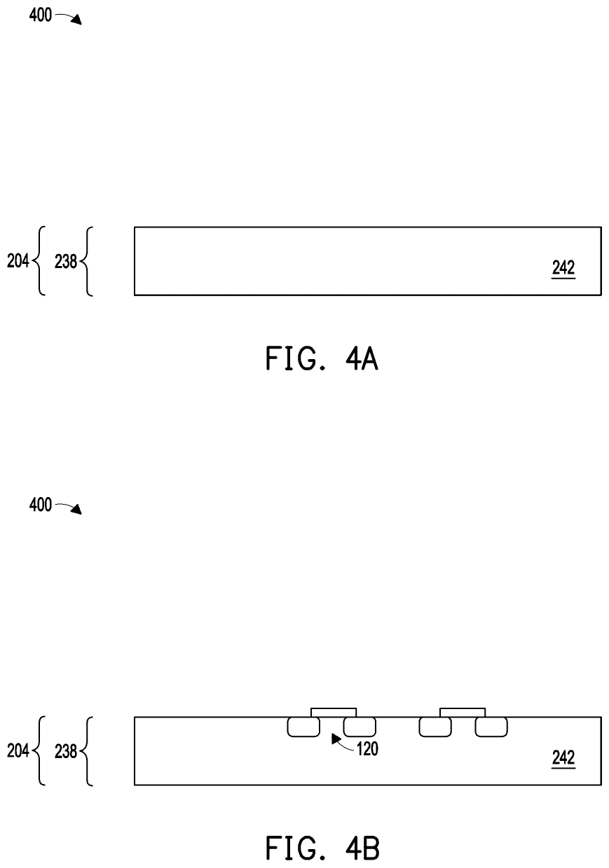

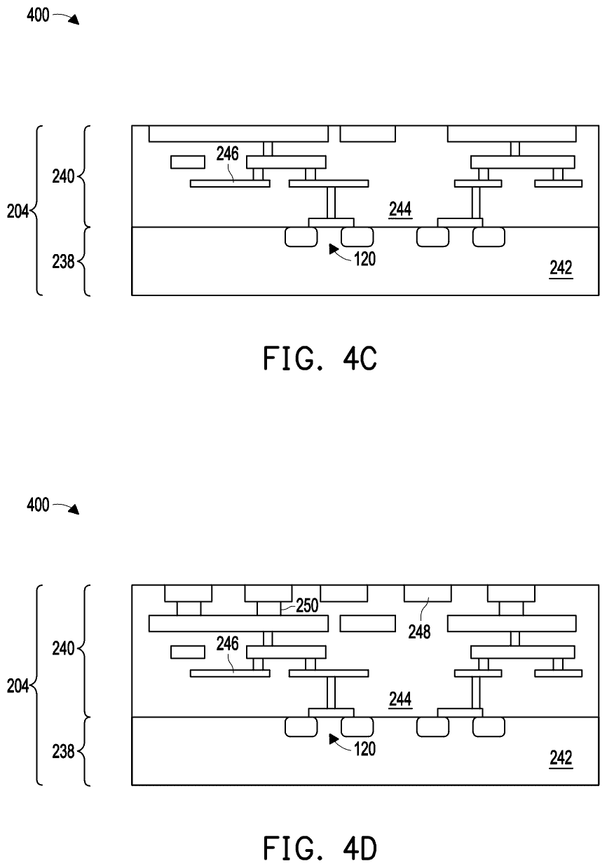

FIGS. 4A-4D are diagrams of an example implementation 400 of forming the semiconductor die 204 (or a portion thereof) described herein. In some implementations, the example implementation 400 includes an example front side process for the semiconductor die 204. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

Turning to FIG. 4A, one or more of the operations in the example implementation 400 may be performed in connection with the substrate layer 242 of the device layer 238 of the semiconductor die 204. The substrate layer 242 may be provided in the form of a semiconductor wafer (e.g., a silicon wafer), an SOI wafer, or another type of semiconductor substrate.

As shown in FIG. 4B, the integrated circuit devices of the image processing circuits 120 may be formed in and/or on the front side of the substrate layer 242 of the device layer 238. For example, a deposition tool may be used to perform various deposition operations to deposit layers of the integrated circuit devices of the image processing circuits 120, and/or to deposit photoresist layers for etching the substrate layer 242 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 242 and/or portions of the deposited layers to form the integrated circuit devices of the image processing circuits 120. As another example, a planarization tool may be used to planarize portions of the integrated circuit devices of the image processing circuits 120. As another example, an ion implantation tool may be used to implant ions in the substrate layer 242 to dope portions of the substrate layer 242 with one or more types of dopants (e.g., p-type dopants, n-type dopants).

As shown in FIG. 4C, the interconnect layer 240 of the semiconductor die 204 may be formed above the front side of the substrate layer 242 of the semiconductor die 204. One or more semiconductor processing tools may be used to form the interconnect layer 240 by forming one or more dielectric layers of the dielectric region 244 of the interconnect layer 240 and forming a plurality of conductive structures 246 in the dielectric layer(s) of the dielectric region 244. For example, a deposition tool may be used to deposit a first dielectric layer of the dielectric region 244 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 246 in the recesses (e.g., using a CVD technique, an ALD technique, a PVD technique, an electroplating technique, and/or another type of deposition technique). At least a portion of the first layer of conductive structures 246 may be electrically connected and/or physically connected with the integrated circuit devices of the image processing circuits 120 in the substrate layer 242 (e.g., directly connected or connected through contacts). Similar processing operations may be performed to form additional layers of the interconnect layer 240 until a sufficient or desired arrangement of conductive structures 246 is achieved.

As shown in FIG. 4D, the bonding vias 250 may be formed on one or more conductive structures 246 in the interconnect layer 240, and bonding pads 248 may be formed above and/or on the bonding vias 250.

As indicated above, FIGS. 4A-4D are provided as an example. Other examples may differ from what is described with regard to FIGS. 4A-4D.

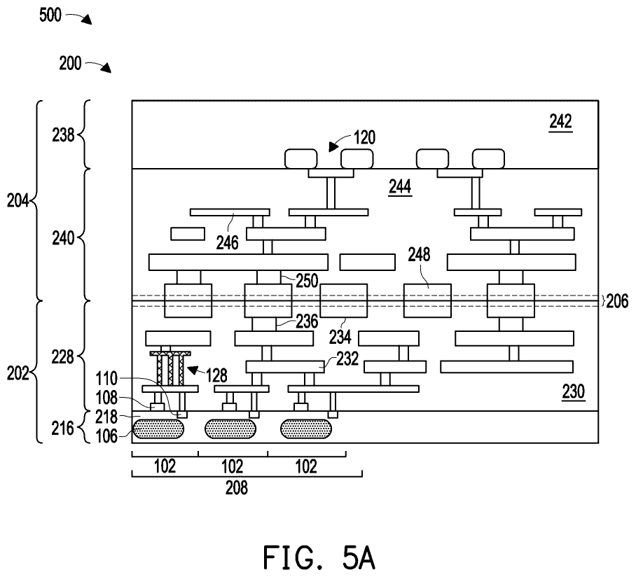

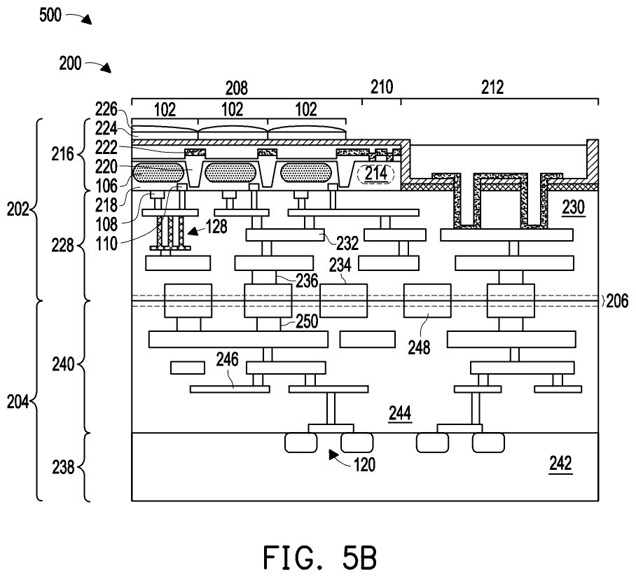

FIGS. 5A and 5B are diagrams of an example implementation 500 of forming the semiconductor device 200 (or a portion thereof) described herein. For example, the example implementation 500 may include an example of bonding the semiconductor dies 202 and 204 of the semiconductor device 200, and performing back side processing on the semiconductor die 202 after bonding. In some implementations, one or more semiconductor processing tools may be used to perform one or more of the operations described in connection with the example implementation 500, such as a deposition tool, an exposure tool, a developer tool, an etch tool, a planarization tool, a bonding tool, and/or another type of semiconductor processing tool.

As shown in FIG. 5A, a bonding operation is performed to bond the semiconductor die 202 and the semiconductor die 204 at the bonding interface 206 such that the semiconductor die 202 and the semiconductor die 204 are vertically arranged or stacked in the semiconductor device 200. The semiconductor die 202 and the semiconductor die 204 may be vertically arranged or stacked in a wafer-on-wafer configuration, a die-on-wafer configuration, a die-on-die configuration, and/or another direct bonding configuration. A bonding tool may be used to perform the bonding operation to bond the semiconductor die 202 and the semiconductor die 204 at the bonding interface 206. The bonding operation may include forming a direct bond between the semiconductor die 202 and the semiconductor die 204 through a direct physical connection of the bonding pads 234 of the semiconductor die 202 with the bonding pads 248 of the semiconductor die 204, and through a direct physical connection of the dielectric region 230 of the semiconductor die 202 with the dielectric region 244 of the semiconductor die 204. In this way, the interconnect layer 228 on the front side of the semiconductor die 202 and the interconnect layer 240 on the front side of the semiconductor die 204 are facing each other in the semiconductor device 200.

As shown in FIG. 5B, back side processing may be performed on the back side of the semiconductor die 202 after the semiconductor dies 202 and 204 are bonded at the bonding interface 206. The back side processing may include additional processing to form the pixel sensor array 208, the BLC region 210, and/or the bonding pad region 212. For example, the DTI structure 220 may be formed in the back side of the substrate layer 218 such that the DTI structure 220 laterally surrounds the photodiodes 106 of the pixel sensors 100. As another example, the grid structure 222 may be formed above the back side of the substrate layer 218, the color filter regions 224 may be above the photodiodes 106 on the back side of the substrate layer 218, and the micro-lenses 226 may be formed above the color filter regions 224. As another example, a metal shielding layer may be formed over the region 214 in the BLC region 210. As another example, a bonding pad structure may be formed in the bonding pad region 212.

As indicated above, FIGS. 5A and 5B are provided as an example. Other examples may differ from what is described with regard to FIGS. 5A and 5B.

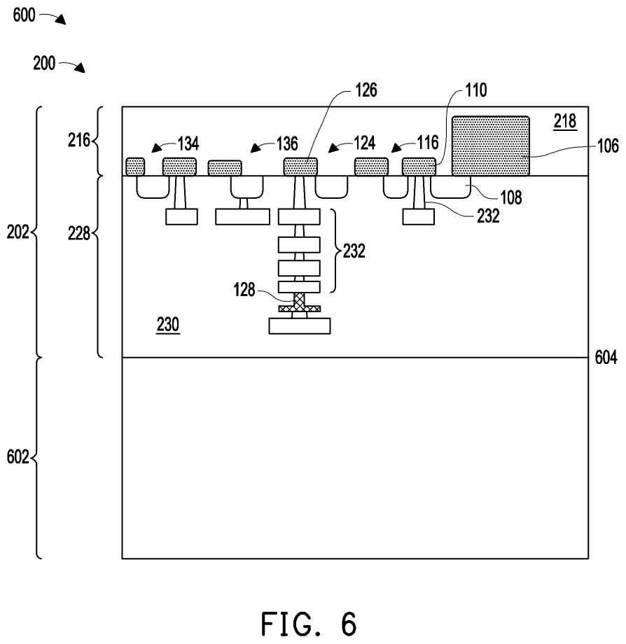

FIG. 6 illustrates a cross-sectional view of a structural implementation 600 of the semiconductor device 200. As shown in FIG. 6, the semiconductor die 202 may be bonded to a substrate 602 at a bonding interface 604. The semiconductor die 202 and substrate 602 may be vertically stacked or vertically arranged in the semiconductor device 200. The substrate 602 can be, for example, a carrier wafer. In some implementations, the substrate 602 may be, for example, a silicon nitride (SiₓN_{y}) wafer that is bonded to a surface of a dielectric layer of the dielectric region 230 using a silicon oxynitride (SiON) bond. The silicon oxynitride (SiON) bond may be formed between the silicon nitride (SiₓN_{y}) of the substrate 602 and silicon oxide (SiOₓ) of the dielectric layer of the dielectric region 230. Alternatively, the substrate 602 may be a glass substrate that is attached to a surface of a dielectric layer of the dielectric region 230 by an adhesive. The adhesive may be, for example, a polymeric material, such as a polyimide-based material, and/or a thermoplastic polymer.

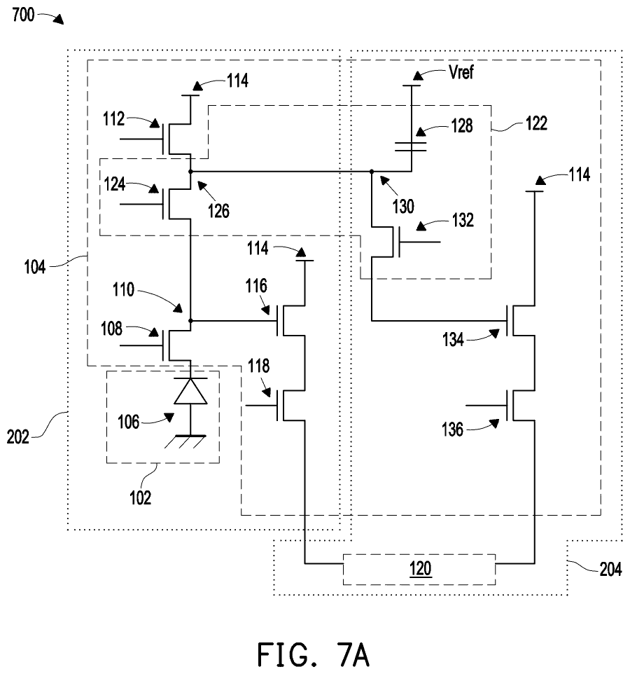

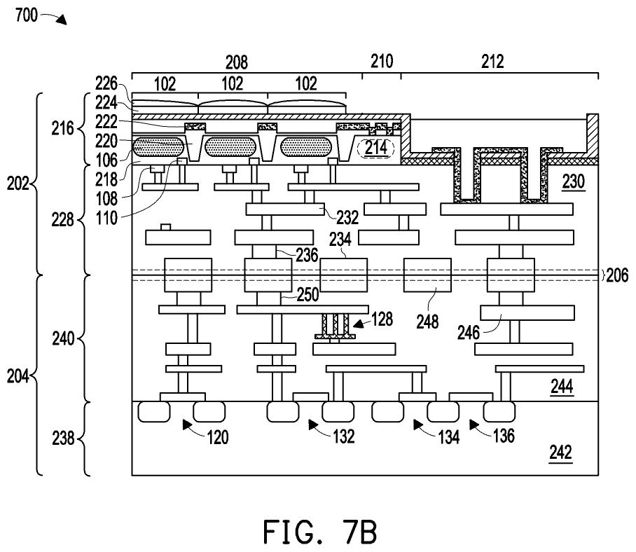

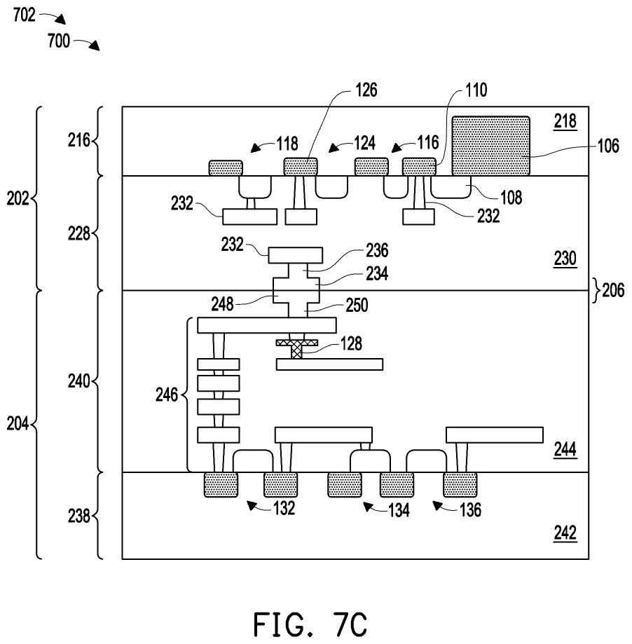

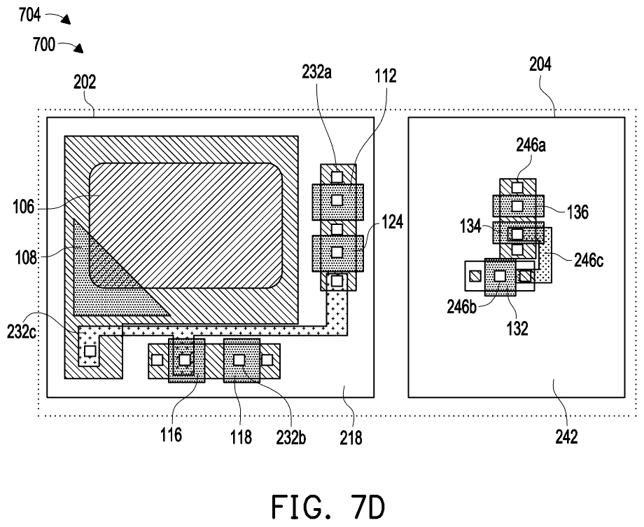

FIGS. 7A and 7B are diagrams of an example semiconductor device 700 described herein. The semiconductor device 700 includes an image sensor device such as a CMOS image sensor device that includes one or more pixel sensors 100. FIG. 7A illustrates an example distribution of components across a plurality of semiconductor dies of the semiconductor device 700. FIG. 7B illustrates a cross-sectional view of a structural implementation of the semiconductor device 700.

As shown in FIG. 7A, the pixel sensor 100, including the sensing region 102 and a first portion of the control circuitry region 104, may be included on a semiconductor die 202. The semiconductor die 202 may be an image sensor die of the semiconductor device 200. The first portion of the control circuitry region 104 may include the photodiode 106, the transfer gate 108, the floating diffusion node 110, the reset transistor 112, the first source-follower gate 116, the first row-select gate 118, and the first conversion gain transistor 124. A second portion of the control circuitry region 104, and the image processing circuit 120 may be included on the semiconductor die 204. The second portion of the control circuitry region 104 may include the capacitor 128, the second conversion gain transistor 132, the second source-follower gate 134, and the second row-select gate 136. The semiconductor die 204 may be an ISP die and/or an ASIC die.

As shown in FIG. 7B, the semiconductor dies 202 and 204 may be vertically stacked or vertically arranged in the semiconductor device 700. The semiconductor die 202 and the semiconductor die 204 may be bonded at a bonding interface 206. Thus, the semiconductor device 700 may be a 3D CIS because of the vertical arrangement of the semiconductor dies 202 and 204. The semiconductor device 700 is similar to the semiconductor device 200 described in connection with FIGS. 2A and 2B, except that the second portion of the control circuitry region 104, including the capacitor 128, the second conversion gain transistor 132, the second source-follower gate 134, and the second row-select gate 136, is formed on the semiconductor die 204 instead of the semiconductor die 202. FIG. 7B illustrates that the capacitor 128 is formed in the dielectric region 244 of the interconnect layer 240 of the semiconductor die 204. The capacitor 128 may be connected to one or more conductive structures 246, which may connect to the capacitor 128 to, for example, the first conversion gain transistor 124 and the second conversion gain transistor 132. FIG. 7B further illustrates that, in addition to the image processing circuit 120, the second conversion gain transistor 132, the second source-follower gate 134, and the second row-select gate 136 are formed in and/or on the substrate layer of the semiconductor die 204.

FIG. 7C illustrates a cross-sectional view of a structural implementation 702 of the semiconductor device 700. As shown in FIG. 7C, the semiconductor dies 202 and 204 may be vertically stacked or vertically arranged in the semiconductor device 700. The semiconductor die 202 and the semiconductor die 204 may be bonded at a bonding interface 206 through bonding pads 234 and 248. In the structural implementation 702, a photodiode 106 of the sensing region 102 of a pixel sensor 100 is included in the substrate layer 218 of the semiconductor die 202. The substrate layer 218 further includes source/drain regions of the transfer gate 108, of the first source-follower gate 116, of the first row-select gate 118, and of the first conversion gain transistor 124. The first junction 126 is further illustrated in the substrate layer 218. The floating diffusion node 110 may be a source/drain region of the transfer gate 108. The first source-follower gate 116, the first row-select gate 118, the transfer gate 108, and a gate of the first conversion gain transistor 124 are formed on the substrate layer 218.

Not shown in FIG. 7C are additional components of the control circuitry region 104 of a pixel sensor 100 that may be included in the substrate layer 218. Such components may include, for example, the reset transistor 112, among other examples.

The dielectric region 230 of the interconnect layer 228 may include a plurality of conductive structures 232 (e.g., electrically conductive structures) in the dielectric region 230. The conductive structures 232 are electrically coupled and/or physically coupled to the source/drain regions of the transfer gate 108, of the first source-follower gate 116, of the first row-select gate 118, and/or of the first conversion gain transistor 124. The conductive structures 232 may also be electrically coupled to the transfer gate 108, the floating diffusion node 110, the first source-follower gate 116, the first row-select gate 118, the first conversion gain transistor 124, the first junction 126, and/or other structures of the pixel sensor 100 in the device layer 216. The conductive structures 232 may be electrically interconnected together in the interconnect layer 228.

The bonding interface 206 between the semiconductor dies 202 and 204 may include a plurality of bonding pads 234 in the dielectric region 230. The bonding pads 234 may be electrically coupled to the conductive structures 232 in the interconnect layer 228 by bonding vias 236 and/or other types of conductive structures.

The semiconductor die 204 may include the second portion of the control circuitry region 104, which includes the capacitor 128, the second conversion gain transistor 132, the second source-follower gate 134, and the second row-select gate 136. The semiconductor die 204 may include one or more components of the image processing circuit 120, such as one or more transistors, coupled to the pixel sensor 100 of the semiconductor device 200. The semiconductor die 204 may include a device layer 238 and an interconnect layer 240 vertically adjacent to the device layer 238. The device layer 238 may include a substrate layer 242. The second conversion gain transistor 132, the second source-follower gate 134, the second row-select gate 136, and the one or more components of the image processing circuit 120 may be included in and/or on the substrate layer 242. For example, the substrate layer 242 includes source/drain regions of the second conversion gain transistor 132, of the second source-follower gate 134, and of the second row-select gate 136. The second source-follower gate 134, the second row-select gate 136, and a gate of the second conversion gain transistor 132 are formed on the substrate layer 242. Not shown in FIG. 7C are the one or more components of the image processing circuit 120 that may be included in and/or on the substrate layer 242.

The interconnect layer 240 may include a similar combination and/or arrangement of structures and/or layers as the interconnect layer 228 of the semiconductor die 202. For example, the interconnect layer 240 may include a dielectric region 244 (similar to the dielectric region 230) and a combination of conductive structures 246 (similar to the conductive structures 232) in the dielectric region 244. Moreover, the interconnect layer 240 may include bonding pads 248 that are electrically coupled to one or more of the conductive structures 246 by bonding vias 250. The capacitor 128 is formed in the dielectric region 244 of the interconnect layer 240 of the semiconductor die 204. The capacitor 128 may be electrically and/or physically connected to one or more conductive structures 246, which may connect to the capacitor 128 to, for example, the second conversion gain transistor 132. The capacitor 128 may be electrically coupled to the first junction 126 through the bonding pads 234 and 248, the bonding vias 236 and 250, one or more conductive structures 246 in the interconnect layer 240, and one or more conductive structures 232 in the interconnect layer 228.

FIG. 7D is a diagram of an example implementation 704 of a portion of the semiconductor device 700 described herein. In the example implementation 704, FIG. 7D depicts top views of the semiconductor dies 202 and 204. As shown in FIG. 7D, the semiconductor die 202 includes the photodiode 106, the transfer gate 108, the reset transistor 112, the first source-follower gate 116, the first row-select gate 118 adjacent to the first source-follower gate 116, and the first conversion gain transistor 124 adjacent to the reset transistor 112. The semiconductor die 204 includes the second conversion gain transistor 132, the second source-follower gate 134, and the second row-select gate 136 adjacent to the second source-follower gate 134. The substrate layers 218 and 242 include source/drain regions corresponding to adjacent gates of a given transistor.

The conductive structures 232a and 232b respectively contacting the source/drain regions and gates respectively correspond to source/drain interconnects and gate interconnects. A conductive structure 232c connects a source/drain region of the first conversion gain transistor 124 with a source/drain region of the transfer gate 108 and with the first source-follower gate 116. The conductive structures 246a and 246b respectively contacting the source/drain regions and gates respectively correspond to source/drain interconnects and gate interconnects. A conductive structure 246c connects a source/drain region of the second conversion gain transistor 132 with the second source-follower gate 134. The conductive structures 232a, 232b, 232c, 246a, 246b, and/or 246c may include a combination of conductive structures that extend primarily horizontally in the interconnect layer 228 or interconnect layer 240 (e.g., trenches, conductive lines) and that are interconnected by interconnect structures (e.g., vias) that extend primarily vertically in the interconnect layer 228 or interconnect layer 240.

As indicated above, FIGS. 7A-7D are provided as examples. Other examples may differ from what is described with regard to FIGS. 7A-7D.

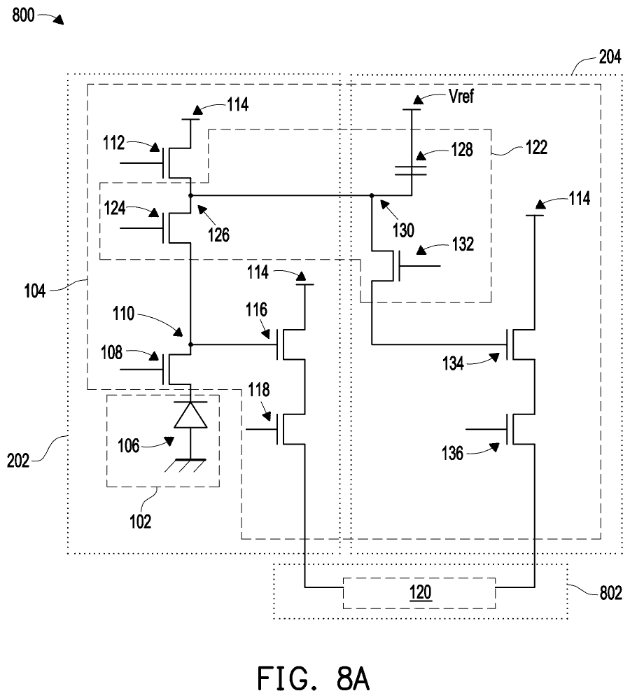

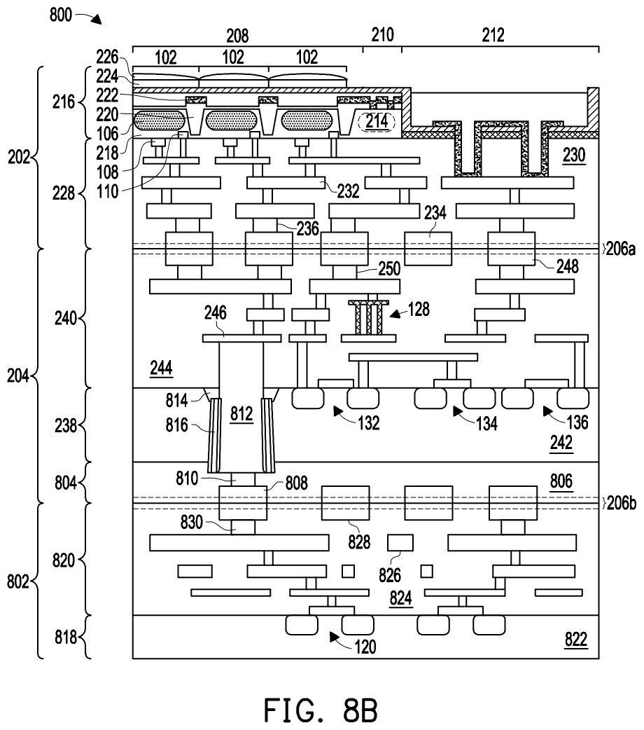

FIGS. 8A and 8B are diagrams of an example semiconductor device 800 described herein. The semiconductor device 800 includes an image sensor device such as a CMOS image sensor device that includes one or more pixel sensors 100. FIG. 8A illustrates an example distribution of components across a plurality of semiconductor dies of the semiconductor device 800. FIG. 8B illustrates a cross-sectional view of a structural implementation of the semiconductor device 800.

As shown in FIG. 8A, the sensing region 102 of a pixel sensor 100 may be included on the semiconductor die 202 (e.g., an image sensor die). Moreover, a first portion of the control circuitry region 104 of the pixel sensor 100, including the transfer gate 108, the floating diffusion node 110, the reset transistor 112, the first source-follower gate 116, the first row-select gate 118, and the first conversion gain transistor 124, may be included on the semiconductor die 202. A second portion of the control circuitry region 104 of the pixel sensor 100 may be included on the semiconductor die 204. The second portion of the control circuitry region 104 may include the capacitor 128, the second conversion gain transistor 132, the second source-follower gate 134, and the second row-select gate 136. Thus, the control circuitry region 104 of the pixel sensor is distributed across a plurality of semiconductor dies. The semiconductor die 204 may be an ASIC die. The image processing circuit 120 may be included on a semiconductor die 802 (e.g., an ISP die).

As shown in FIG. 8B, the semiconductor dies 202, 204, and 802 may be vertically stacked or vertically arranged in the semiconductor device 800. The semiconductor die 202 and the semiconductor die 204 may be bonded at a bonding interface 206a, and the semiconductor die 204 and the semiconductor die 802 may be bonded at a bonding interface 206b. The semiconductor dies 202 and 204 may each include a similar combination and arrangement of layers and/or structures as in the semiconductor device 200. However, the capacitors 128 are included in the semiconductor die 204 of the semiconductor device 800 instead of in the semiconductor die 202.

As further shown in FIG. 8B, the semiconductor die 204 may include another interconnect layer 804. The interconnect layer 804 may be located on a second side (e.g., a back side) of the substrate layer 242 such that the interconnect layers 240 and 804 are located on vertically opposing sides of the substrate layer 242 of the semiconductor die 204. The interconnect layer 804 may be configured to route signals and/or power between the semiconductor dies 204 and 802. The interconnect layer 804 may include a similar combination and/or arrangement of structures and/or layers as the interconnect layer 240 of the semiconductor die 204. For example, the interconnect layer 804 may include a dielectric region 806 (similar to the dielectric region 244), bonding pads 808, and bonding vias 810. The bonding pads 808 enable the semiconductor die 204 to be bonded to the semiconductor die 802 at the bonding interface 206b, and the bonding vias 810 electrically connect one or more of the bonding pads 808 to one or more elongated conductive structures 812.

The one or more elongated conductive structures 812 may be included in the semiconductor die 204. An elongated conductive structure 812 may extend between the interconnect layers 240 and 804 through the substrate layer 242 of the device layer 238. An elongated conductive structure 812 may include a through substrate via (TSV), a metal pillar, a metal column, and/or another type of vertically elongated conductive structure that physically connects and electrically connects with a conductive structure 246 (e.g., a metal pad) in the interconnect layer 240 at a first end, and that physically connects and electrically connects with a bonding via 810 in the interconnect layer 804. An elongated conductive structure 812 may be referred to as a TSV structure in that the elongated conductive structure 812 extends fully through the substrate layer 242 (e.g., a semiconductor substrate such as a silicon substrate) of the device layer 238, as opposed to extending fully through a dielectric layer or an insulator layer. An elongated conductive structure 812 may further extend through a shallow trench isolation (STI) region 814 that is included in the substrate layer 242 of the device layer 238.

An elongated conductive structure 812 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. An STI region 814 may include one or more dielectric materials such as a silicon oxide material (SiOₓ such as SiO₂), a silicon nitride material (SiₓN_{y} such Si₃N₄), and/or another suitable dielectric material.

One or more liners 816 may be included between the sidewalls of the elongated conductive structure 812 and the substrate layer 242. The one or more liners 816 may include adhesion liners, barrier liners, diffusion liners, and/or another type of liners. In some implementations, a liner 816 includes a high-k dielectric liner that includes a high-k dielectric material having a dielectric constant that is greater than approximately 3.9. Examples of such materials include a silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, a liner 816 includes a low-k dielectric liner that includes a low-k dielectric material. Examples of such materials include a silicon oxide (SiOₓ), an undoped silicate glass (USG), a boron-containing silicate glass (BSG), and/or a fluorine-containing silicate glass (FSG), among other examples.

As further shown in FIG. 8B, the capacitors 128 may be included in the interconnect layer 240 of the semiconductor die 204. In other words, the capacitors 128 may be included on the front side of the semiconductor die 204. The second conversion gain transistor 132, the second source-follower gate 134, and/or the second row-select gate 136 may be included in and/or on the substrate layer 242 of the semiconductor die 204. In some implementations, the second conversion gain transistor 132, the second source-follower gate 134, and/or the second row-select gate 136 may be included in and/or on a front side of the substrate layer 242 facing the interconnect layer 240. In some implementations, the second conversion gain transistor 132, the second source-follower gate 134, and/or the second row-select gate 136 may be included in and/or on a back side of the substrate layer 242 facing the interconnect layer 804.

The semiconductor die 802 may include a device layer 818 and an interconnect layer 820 vertically adjacent to the device layer 818. The device layer 818 may include a substrate layer 822. The substrate layer 822 may include a silicon (Si) substrate and/or another type of semiconductor substrate. The integrated circuit devices of the image processing circuits 120 may be included in and/or on the substrate layer 822. The image processing circuits 120 of the semiconductor die 802 may be configured to perform functions such as compression, storage, file management, and/or other functions associated with images and/or video generated by the semiconductor device 800. The integrated circuit devices of the image processing circuits 120 may include transistors, capacitors, resistors, and/or other integrated circuit devices.

The interconnect layer 804 may be located vertically adjacent to the front side of the substrate layer 822. The interconnect layer 820 may include a similar combination and/or arrangement of structures and/or layers as the interconnect layer 240 of the semiconductor die 204. For example, the interconnect layer 820 may include a dielectric region 824 (similar to the dielectric region 244) and a combination of conductive structures 826 (similar to the conductive structures 246) in the dielectric region 824. Moreover, the interconnect layer 820 may include bonding pads 828 that are electrically coupled to one or more of the conductive structures 826 through bonding vias 830. These layers and/or structures may have a reversed vertical arrangement relative to the interconnect layer 804, which enables the semiconductor die 204 and the semiconductor die 802 to be bonded at the bonding interface 206b such that the interconnect layer 804 and the interconnect layer 820 are facing each other and bonded together.

At the bonding interface 206b, the bonding pads 808 of the semiconductor die 204 and bonding pads 828 of the semiconductor die 802 are directly bonded by metal-to-metal bonds. Moreover, the dielectric region 806 of the semiconductor die 204 and the dielectric region 824 of the semiconductor die 802 are directly bonded by dielectric-to-dielectric bonds.

As indicated above, FIGS. 8A and 8B are provided as an example. Other examples may differ from what is described with regard to FIGS. 8A and 8B.

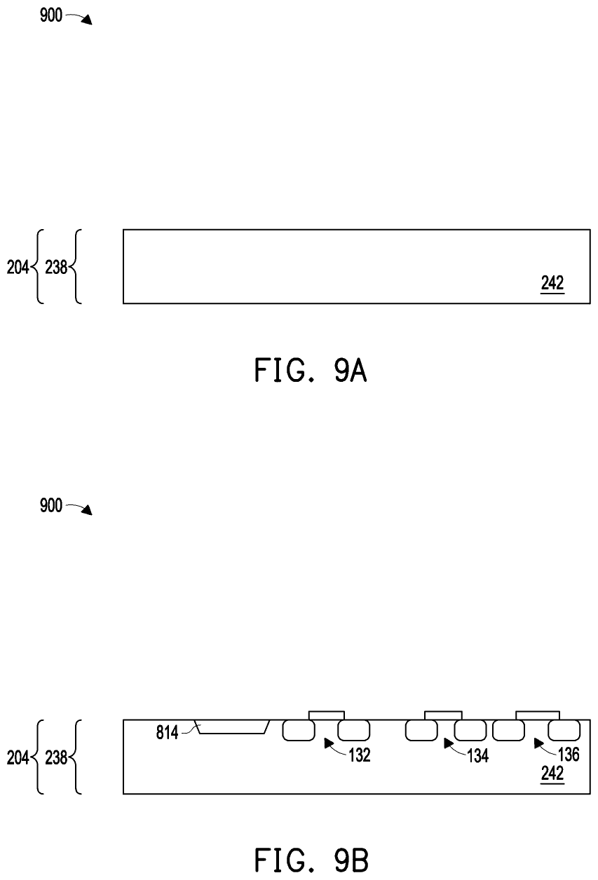

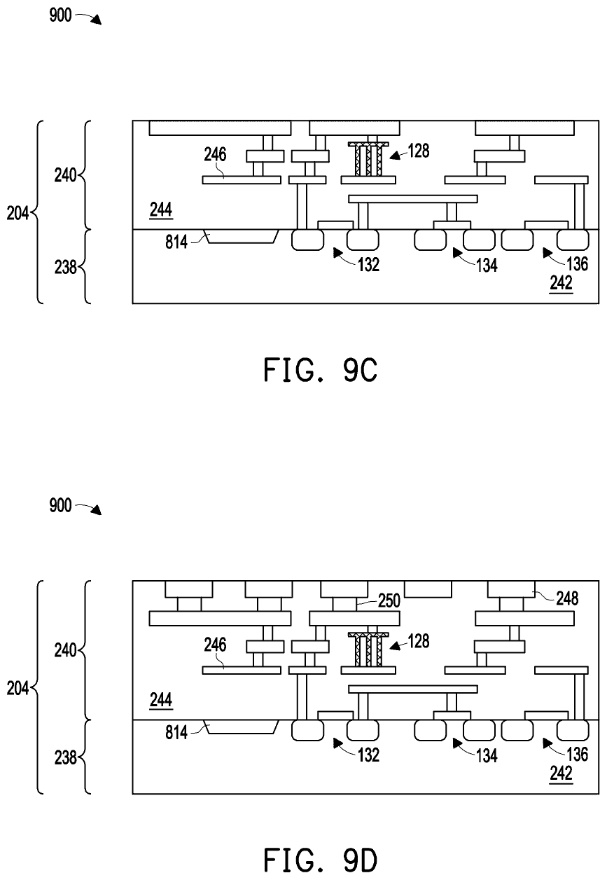

FIGS. 9A-9D are diagrams of an example implementation 900 of forming the semiconductor die 204 (or a portion thereof) of the semiconductor device 800 described herein. In some implementations, the example implementation 900 includes an example front side process for the semiconductor die 204. In some implementations, one or more semiconductor processing tools may be used to perform one or more of the operations described in connection with the example implementation 900, such as a deposition tool, an exposure tool, a developer tool, an etch tool, a planarization tool, a plating tool, and/or another type of semiconductor processing tool.

Turning to FIG. 9A, one or more of the operations in the example implementation 900 may be performed in connection with the substrate layer 242 of the device layer 238 of the semiconductor die 204. The substrate layer 242 may be provided in the form of a semiconductor wafer (e.g., a silicon wafer), an SOI wafer, or another type of semiconductor substrate.

As shown in FIG. 9B, the integrated circuit devices may be formed in and/or on the front side of the substrate layer 242 of the semiconductor die 204. For example, one or more of the second conversion gain transistor 132, the second source-follower gate 134, and/or the second row-select gate 136 may be formed in and/or on the front side of the substrate layer 242.

One or more semiconductor processing tools may be used to form one or more portions of the integrated circuit devices. For example, a deposition tool may be used to perform various deposition operations to deposit layers of the integrated circuit devices, and/or to deposit photoresist layers for etching the substrate layer 242 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate layer 242 and/or portions of the deposited layers to form the integrated circuit devices. As another example, a planarization tool may be used to planarize portions of the integrated circuit devices. As another example, an ion implantation tool may be used to implant ions in the substrate layer 242 to dope portions of the substrate layer 242 with one or more types of dopants (e.g., p-type dopants, n-type dopants).

As further shown in FIG. 9B, an STI region 814 may be formed in the front side of the substrate layer 242. The STI region 814 may be formed in a recess in the substrate layer 242. In some implementations, a pattern in a photoresist layer is used to etch the substrate layer 242 to form the recess in the substrate layer 242. In these implementations, a deposition tool may be used to form the photoresist layer on the substrate layer 242. An exposure tool may be used to expose the photoresist layer to a radiation source to pattern the photoresist layer. A developer tool may be used to develop and remove portions of the photoresist layer to expose the pattern. An etch tool may be used to etch the substrate layer 242 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate layer 242 based on a pattern.

A deposition tool may be used to deposit the dielectric material of the STI region 814 in the recess using a CVD technique, an ALD technique, a PVD technique, an oxidation technique, and/or another suitable deposition technique. The dielectric material of the STI region 814 may be deposited in one or more deposition operations. In some implementations, a planarization tool may be used to perform a planarization operation (e.g., a CMP operation) to planarize the STI region 814 after the dielectric material of the STI region 814 is deposited.

As shown in FIG. 9C, the interconnect layer 240 of the semiconductor die 204 may be formed above the front side of the substrate layer 242 of the semiconductor die 204. One or more semiconductor processing tools may be used to form the interconnect layer 240 by forming one or more dielectric layers of the dielectric region 244 of the interconnect layer 240 and forming a plurality of conductive structures 246 in the dielectric layer(s) of the dielectric region 244. For example, a deposition tool may be used to deposit a first dielectric layer of the dielectric region 244 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer, a metallization layer) of one or more conductive structures 246 in the recesses (e.g., using a CVD technique, an ALD technique, a PVD technique, an electroplating technique, and/or another type of deposition technique). At least a portion of the first layer of conductive structures 246 may be electrically connected and/or physically connected with the integrated circuit devices in the substrate layer 242 (e.g., directly connected or connected through contacts). Similar processing operations may be performed to form additional layers of the interconnect layer 240 until a sufficient or desired arrangement of conductive structures 246 is achieved.

As further shown in FIG. 9C, one or more capacitor structures, such as one or more capacitors 128, may be formed above the front side of the substrate layer 242 in the interconnect layer 240. In some implementations, a capacitor 128 is formed by depositing a metal-insulator-metal (MIM) layer stack, and etching the MIM layer stack to define a planar capacitor structure. In some implementations, in these examples, a capacitor 128 is formed by forming a trench in the dielectric region 244 and forming the MIM layer stack in the trench to define a trench capacitor structure or DTC structure. Additionally and/or alternatively, one or more of the capacitors 128 may be formed in the substrate layer 242.

As shown in FIG. 9D, the bonding vias 250 may be formed on one or more conductive structures 246 in the interconnect layer 240, and bonding pads 248 may be formed above and/or on the bonding vias 250.

As indicated above, FIGS. 9A-9D are provided as an example. Other examples may differ from what is described with regard to FIGS. 9A-9D.

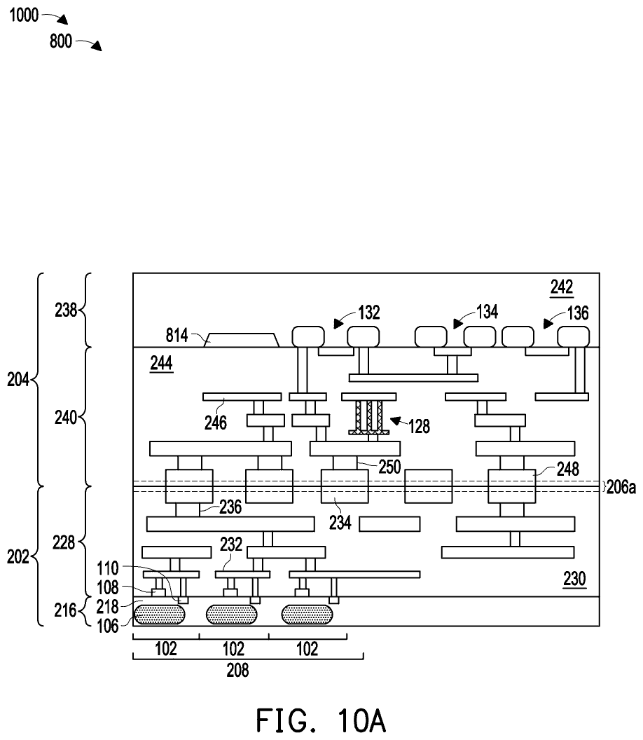

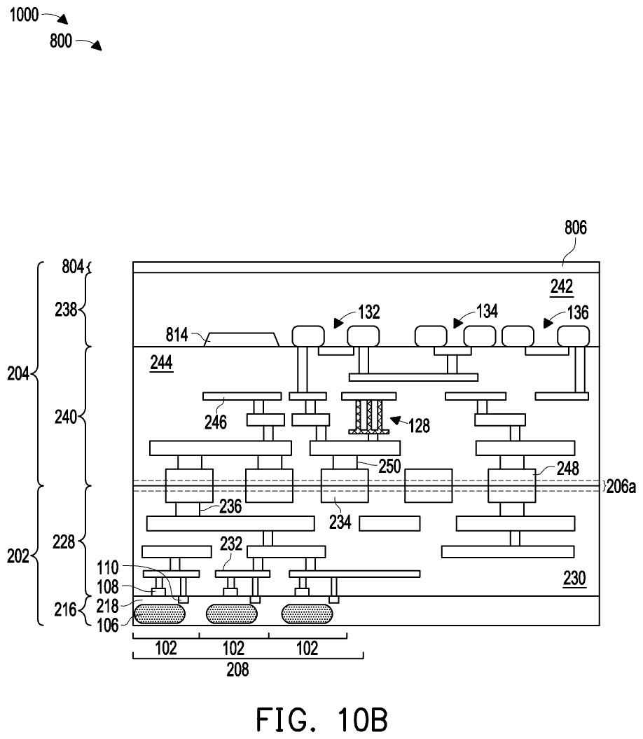

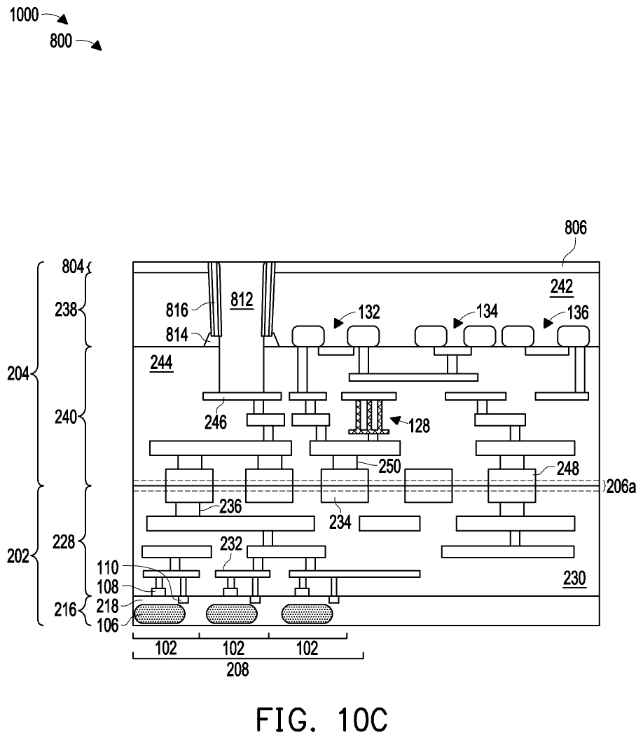

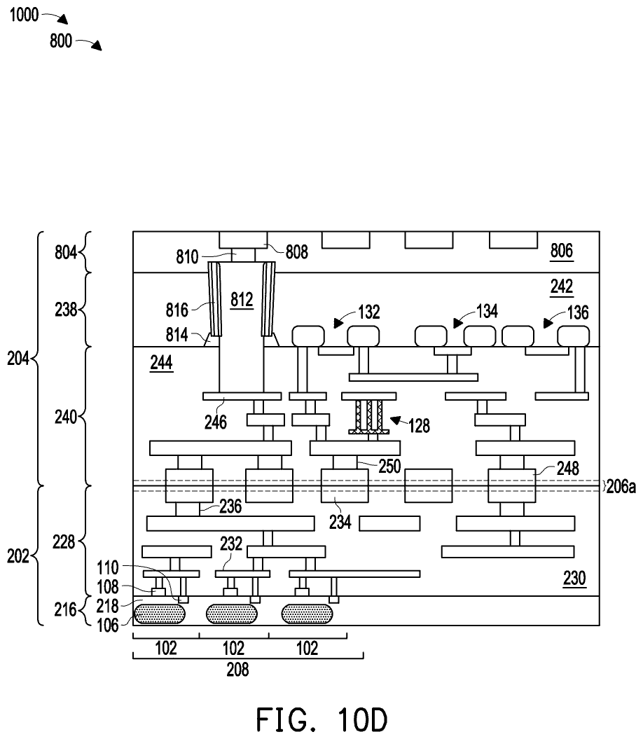

FIGS. 10A-10D are diagrams of an example implementation 1000 of forming the semiconductor device 800 (or a portion thereof) described herein. For example, the example implementation 1000 may include an example of bonding the semiconductor dies 202 and 204 of the semiconductor device 800, and performing back side processing on the semiconductor die 204 after bonding. In some implementations, one or more semiconductor processing tools may be used to perform one or more of the operations described in connection with the example implementation 1000, such as a deposition tool, an exposure tool, a developer tool, an etch tool, a planarization tool, a bonding tool, and/or another type of semiconductor processing tool.

As shown in FIG. 10A, a bonding operation is performed to bond the semiconductor die 202 and the semiconductor die 204 at the bonding interface 206a such that the semiconductor die 202 and the semiconductor die 204 are vertically arranged or stacked in the semiconductor device 800. The bonding operation may include similar bonding techniques as described in connection with FIG. 5A.

As shown in FIG. 10A, the semiconductor device 800 may be flipped so that back side processing may be performed on the back side of the semiconductor die 204 after the semiconductor dies 202 and 204 are bonded at the bonding interface 206a. While not shown in FIG. 10A, back side processing may include forming one or more integrated circuit devices in and/or on the back side of the substrate layer 242 of the semiconductor die 204.

As shown in FIG. 10B, a portion of the dielectric region 806 of the interconnect layer 804 may be formed over the back side of the substrate layer 242 of the semiconductor die 204.

As shown in FIG. 10C, one or more elongated conductive structures 812 (e.g., one or more TSVs) may be formed through the substrate layer 242 of the semiconductor die 204 such that the one or more elongated conductive structures 812 land on one or more conductive structures 246 in the interconnect layer 240 on the front side of the semiconductor die 204.

To form an elongated conductive structure 812, a recess may be formed through the dielectric region 806, through the substrate layer 242 from the back side of the substrate layer 242, and into the dielectric region 244 of the interconnect layer 240. The recess may extend through the STI region 814 in the substrate layer 242, and into the dielectric region 244 in the interconnect layer 240. A conductive structure 246 in the interconnect layer 240 may be exposed through the recess.

In some implementations, a pattern in a photoresist layer is used to etch the dielectric region 806, the substrate layer 242, the STI region 814, and/or the dielectric region 244 to form the recess. In these implementations, a deposition tool may be used to form the photoresist layer (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the dielectric region 806, through the substrate layer 242, through the STI region 814, and/or into the dielectric region 244 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the material of the elongated conductive structure 812 in the recess using a CVD technique, a PVD technique, an ALD technique, an electroplating technique, and/or another suitable deposition technique. The elongated conductive structure 812 may be deposited in one or more deposition operations. In some implementations, a seed layer is first deposited, and the elongated conductive structure 812 is deposited on the seed layer. In some implementations, one or more liners 816 (e.g., adhesion liners, barrier liners, diffusion liners) are deposited in the recess, and then the elongated conductive structure 812 is deposited on the liners(s) 816. In some implementations, a planarization tool is used to perform a planarization operation (e.g., a CMP operation) to planarize the elongated conductive structure 812 after the elongated conductive structure 812 is deposited.

As shown in FIG. 10D, additional portions of the interconnect layer 804 may be formed above the back side of the substrate layer 242. One or more semiconductor processing tools may be used to form the interconnect layer 804 by forming one or more dielectric layers of the dielectric region 806 of the interconnect layer 804 and forming a plurality of bonding pads 808 and one or more bonding vias 810 in the dielectric layer(s) of the dielectric region 806. For example, a deposition tool may be used to deposit a first dielectric layer of the dielectric region 806 (e.g., using a CVD technique, an ALD technique, a PVD technique, an oxidation technique, and/or another type of deposition technique), an etch tool may be used to remove portions of the first dielectric layer to form recesses in the first dielectric layer, and a deposition tool may be used to form a first layer (e.g., a via layer) of one or more bonding vias 810 in the recesses (e.g., using a CVD technique, an ALD technique, a PVD technique, an electroplating technique, and/or another type of deposition technique). At least a portion of the first layer of the one or more bonding vias 810 may be electrically connected and/or physically connected with the elongated conductive structure 812. Similar processing operations may be performed to form the bonding pads 808 above and/or on the bonding vias 810.

As indicated above, FIGS. 10A-10D are provided as an example. Other examples may differ from what is described with regard to FIGS. 10A-10D.

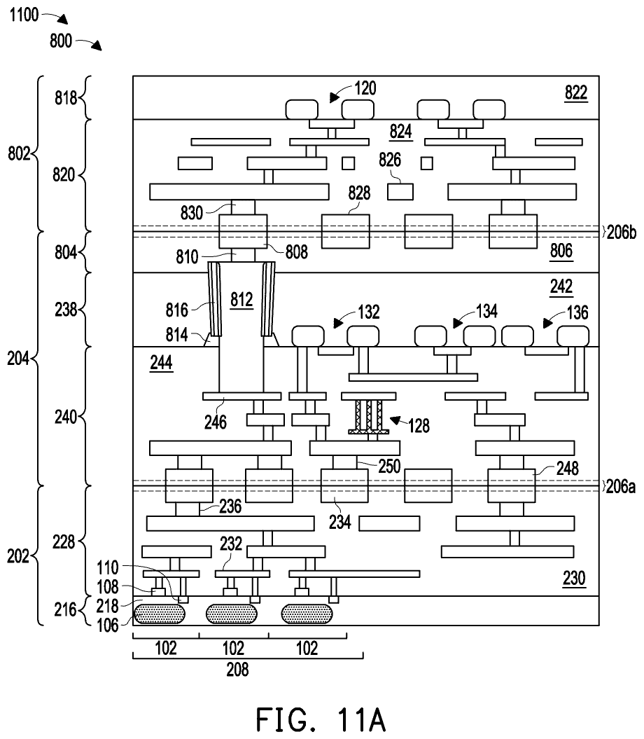

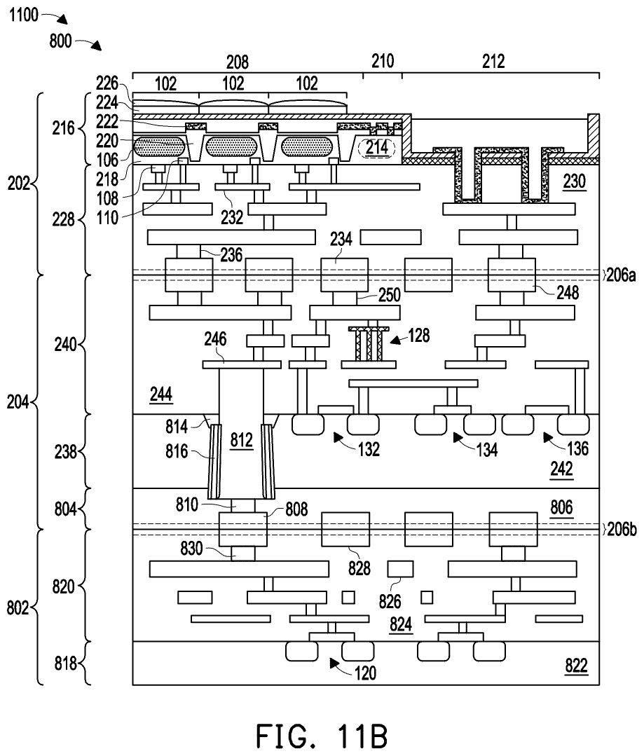

FIGS. 11A and 11B are diagrams of an example implementation 1100 of forming the semiconductor device 800 (or a portion thereof) described herein. For example, the example implementation 1100 may include an example of bonding the semiconductor dies 204 and 802 of the semiconductor device 800, and performing back side processing on the semiconductor die 202 after bonding. In some implementations, one or more semiconductor processing tools may be used to perform one or more of the operations described in connection with the example implementation 1100, such as a deposition tool, an exposure tool, a developer tool, an etch tool, a planarization tool, a bonding tool, and/or another type of semiconductor processing tool.

As shown in FIG. 11A, a bonding operation is performed to bond the semiconductor die 204 and the semiconductor die 802 at the bonding interface 206b such that the semiconductor die 204 and the semiconductor die 802 are vertically arranged or stacked in the semiconductor device 800. The semiconductor die 204 and the semiconductor die 802 may be vertically arranged or stacked in a wafer-on-wafer configuration, a die-on-wafer configuration, a die-on-die configuration, and/or another direct bonding configuration. A bonding tool may be used to perform the bonding operation to bond the semiconductor die 204 and the semiconductor die 802 at the bonding interface 206b. The bonding operation may include forming a direct bond between the semiconductor die 204 and the semiconductor die 802 through a direct physical connection of the bonding pads 808 of the semiconductor die 204 with the bonding pads 828 of the semiconductor die 802, and through a direct physical connection of the dielectric region 806 of the semiconductor die 204 with the dielectric region 824 of the semiconductor die 802. In this way, the interconnect layer 804 on the back side of the semiconductor die 204 and the interconnect layer 820 on the front side of the semiconductor die 802 are facing each other in the semiconductor device 800.

The semiconductor die 802 may be formed by similar operations and/or using similar techniques as described in connection with FIGS. 4A-4D for the semiconductor die 204 and/or similar operations and/or using similar techniques as described in connection with FIGS. 9A-9D for the semiconductor die 204.

As shown in FIG. 11B, back side processing may be performed on the back side of the semiconductor die 204 after the semiconductor dies 204 and 802 are bonded at the bonding interface 206b. The back side processing may include additional processing described in connection with FIG. 5B to form the pixel sensor array 208, the BLC region 210, and/or the bonding pad region 212. For example, the DTI structure 220 may be formed in the back side of the substrate layer 218 such that the DTI structure 220 laterally surrounds the photodiodes 106 of the pixel sensors 100. As another example, the grid structure 222 may be formed above the back side of the substrate layer 218, the color filter regions 224 may be above the photodiodes 106 on the back side of the substrate layer 218, and the micro-lenses 226 may be formed above the color filter regions 224. As another example, a metal shielding layer may be formed over the region 214 in the BLC region 210. As another example, a bonding pad structure may be formed in the bonding pad region 212.

As indicated above, FIGS. 11A and 11B are provided as an example. Other examples may differ from what is described with regard to FIGS. 11A and 11B.

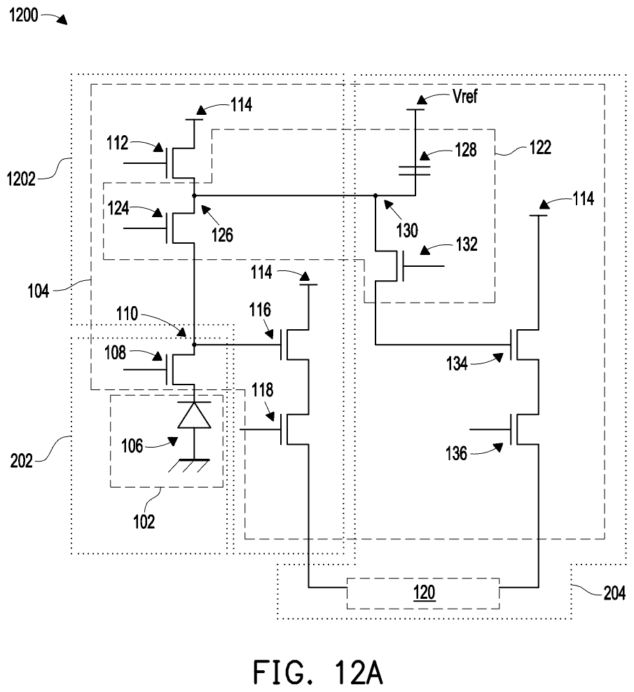

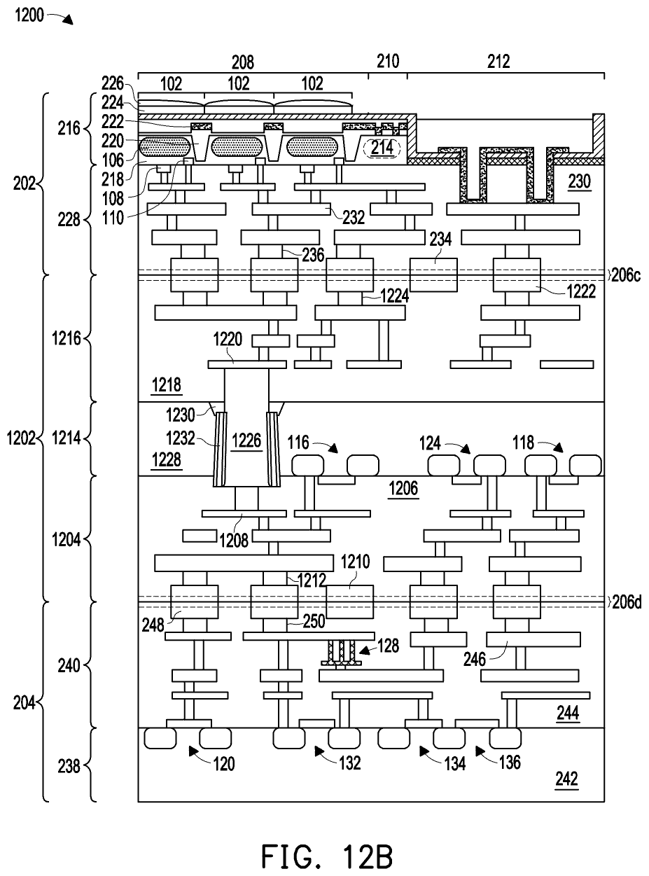

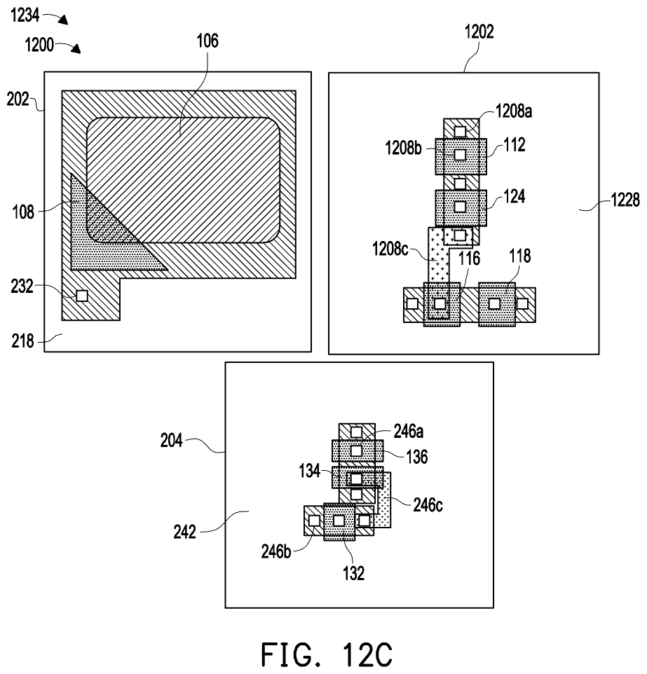

FIGS. 12A and 12B are diagrams of an example semiconductor device 1200 described herein. The semiconductor device 1200 includes an image sensor device such as a CMOS image sensor device that includes one or more pixel sensors 100. FIG. 12A illustrates an example distribution of components across a plurality of semiconductor dies of the semiconductor device 1200. FIG. 12B illustrates a cross-sectional view of a structural implementation of the semiconductor device 1200.

As shown in FIG. 12A, the sensing region 102 of a pixel sensor 100 may be included on the semiconductor die 202 (e.g., an image sensor die). Moreover, a first portion of the control circuitry region 104 of the pixel sensor 100, including the transfer gate 108 and the floating diffusion node 110, may be included on the semiconductor die 202. A second portion of the control circuitry region 104 of the pixel sensor 100 may be included on the semiconductor die 1202. The second portion of the control circuitry region 104 may include the reset transistor 112, the first source-follower gate 116, the first row-select gate 118, and the first conversion gain transistor 124. A third portion of the control circuitry region 104 of the pixel sensor 100, and an image processing circuit 120, may be included on the semiconductor die 204. The third portion of the control circuitry region 104 may include the capacitor 128, the second conversion gain transistor 132, the second source-follower gate 134, and the second row-select gate 136. Thus, the control circuitry region 104 of the pixel sensor is distributed across a plurality of (e.g., three) semiconductor dies. The semiconductor die 204 may be an ASIC die and/or an ISP die.

As shown in FIG. 12B, the semiconductor dies 202, 1202, and 204 may be vertically stacked or vertically arranged in the semiconductor device 1200. The semiconductor die 202 and the semiconductor die 1202 may be bonded at a bonding interface 206c, and the semiconductor die 1202 and the semiconductor die 204 may be bonded at a bonding interface 206d. The semiconductor dies 202 and 204 may each include a similar combination and arrangement of layers and/or structures as in the semiconductor device 700. However, the reset transistor 112, the first source-follower gate 116, the first row-select gate 118, and the first conversion gain transistor 124 are included in the semiconductor die 1202 of the semiconductor device 1200 instead of in the semiconductor die 202.

As further shown in FIG. 12B, the semiconductor die 1202 may include an interconnect layer 1204. The interconnect layer 1204 may be bonded to the interconnect layer 240 of semiconductor die 204 at the bonding interface 206d. The interconnect layer 1204 may be configured to route signals and/or power between the semiconductor dies 204 and 1202. The interconnect layer 1204 may include a similar combination and/or arrangement of structures and/or layers as the interconnect layer 240 of the semiconductor die 204. For example, the interconnect layer 1204 may include a dielectric region 1206 (similar to the dielectric region 244) and a combination of conductive structures 1208 (similar to the conductive structures 246) in the dielectric region 1206. The interconnect layer 1204 may further include bonding pads 1210 and bonding vias 1212. The bonding pads 1210 enable the semiconductor die 204 to be bonded to the semiconductor die 1202 at the bonding interface 206d, and the bonding vias 1212 electrically connect one or more of the bonding pads 1210 to the conductive structures 1208 in the interconnect layer 1204.

The semiconductor die 1202 further includes a device layer 1214 and another interconnect layer 1216. The interconnect layer may include a dielectric region 1218 (similar to the dielectric region 244) and a combination of conductive structures 1220 (similar to the conductive structures 246) in the dielectric region 1218. The interconnect layer 1216 may further include bonding pads 1222 and bonding vias 1224. The bonding pads 1222 enable the semiconductor die 1202 to be bonded to the semiconductor die 202 at the bonding interface 206c, and the bonding vias 1224 electrically connect one or more of the bonding pads 1222 to the conductive structures 1220 in the interconnect layer 1216.

One or more elongated conductive structures 1226 may be included in the semiconductor die 1202. An elongated conductive structure 1226 may extend between the interconnect layers 1204 and 1216 through a substrate layer 1228 of the device layer 1214 of the semiconductor die 1202. The substrate layer 1228 may be similar to the substrate layer 242 of the semiconductor die 204. An elongated conductive structure 1226 may include a through substrate via (TSV), a metal pillar, a metal column, and/or another type of vertically elongated conductive structure that physically connects and electrically connects with a conductive structure 1220 (e.g., a metal pad) in the interconnect layer 1216 at a first end, and that physically connects and electrically connects with a conductive structure 1208 (e.g., a metal pad) in the interconnect layer 1204. An elongated conductive structure 1226 may be referred to as a TSV structure in that the elongated conductive structure 1226 extends fully through the substrate layer 1228 (e.g., a semiconductor substrate such as a silicon substrate) of the device layer 1214, as opposed to extending fully through a dielectric layer or an insulator layer. An elongated conductive structure 1226 may further extend through a shallow trench isolation (STI) region 1230 that is included in the substrate layer 1228 of the device layer 1214.

An elongated conductive structure 1226 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. An STI region 1230 may include one or more dielectric materials such as a silicon oxide material (SiOₓ such as SiO₂), a silicon nitride material (SiₓN_{y} such Si₃N₄), and/or another suitable dielectric material.

One or more liners 1232 may be included between the sidewalls of the elongated conductive structure 1226 and the substrate layer 1228. The one or more liners 1232 may include adhesion liners, barrier liners, diffusion liners, and/or another type of liners. In some implementations, a liner 1232 includes a high-k dielectric liner that includes a high-k dielectric material having a dielectric constant that is greater than approximately 3.9. Examples of such materials include a silicon nitride (SiₓN_{y} such Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOx such as a-LaAlO₃), among other examples. In some implementations, a liner 1232 includes a low-k dielectric liner that includes a low-k dielectric material. Examples of such materials include a silicon oxide (SiOₓ), an undoped silicate glass (USG), a boron-containing silicate glass (BSG), and/or a fluorine-containing silicate glass (FSG), among other examples.

As further shown in FIG. 12B, the capacitors 128 may be included in the interconnect layer 240 of the semiconductor die 204. In other words, the capacitors 128 may be included on the front side of the semiconductor die 204. The integrated circuit devices of the image processing circuits 120, the second conversion gain transistor 132, the second source-follower gate 134, and/or the second row-select gate 136 may be included in and/or on the substrate layer 242 of the semiconductor die 204. In some implementations, the integrated circuit devices of the image processing circuits 120, the second conversion gain transistor 132, the second source-follower gate 134, and/or the second row-select gate 136 may be included in and/or on a front side of the substrate layer 242 facing the interconnect layer 240. In some implementations, the integrated circuit devices of image processing circuits 120, the second conversion gain transistor 132, the second source-follower gate 134, and/or the second row-select gate 136 may be included in and/or on a back side of the substrate layer 242. The image processing circuits 120 of the semiconductor die 204 may be configured to perform functions such as compression, storage, file management, and/or other functions associated with images and/or video generated by the semiconductor device 1200. The integrated circuit devices of the image processing circuits 120 may include transistors, capacitors, resistors, and/or other integrated circuit devices.

The substrate layer 1228 of the semiconductor die 1202 may include a silicon (Si) substrate and/or another type of semiconductor substrate. The reset transistor 112 (not shown), the first source-follower gate 116, the first row-select gate 118, and/or the first conversion gain transistor 124 may be included in and/or on the substrate layer 1228.

The interconnect layer 1216 may be located vertically adjacent to the front side of the substrate layer 1228. At the bonding interface 206c, the bonding pads 234 of the semiconductor die 202 and bonding pads 1222 of the semiconductor die 1202 are directly bonded by metal-to-metal bonds. Moreover, the dielectric region 230 of the semiconductor die 202 and the dielectric region 1218 of the semiconductor die 1202 are directly bonded by dielectric-to-dielectric bonds.

FIG. 12C is a diagram of an example implementation 1234 of a portion of the semiconductor device 1200 described herein. In the example implementation 1234, FIG. 12C depicts top views of the semiconductor dies 202, 204, and 1202. As shown in FIG. 12C, the semiconductor die 202 includes the photodiode 106 and the transfer gate 108. The semiconductor die 1202 includes the reset transistor 112, the first source-follower gate 116, the first row-select gate 118 adjacent to the first source-follower gate 116, and the first conversion gain transistor 124 adjacent to the reset transistor 112. The semiconductor die 204 includes the second conversion gain transistor 132, the second source-follower gate 134, and the second row-select gate 136 adjacent to the second source-follower gate 134. The substrate layers 218, 242, and 1228 include source/drain regions corresponding to adjacent gates of a given transistor.

The conductive structures 1208a and 1208b respectively contacting the source/drain regions and gates respectively correspond to source/drain interconnects and gate interconnects. A conductive structure 1208c connects a source/drain region of the first conversion gain transistor 124 with the first source-follower gate 116. The conductive structures 246a and 246b respectively contacting the source/drain regions and gates respectively correspond to source/drain interconnects and gate interconnects. A conductive structure 246c connects a source/drain region of the second conversion gain transistor 132 with the second source-follower gate 134. The conductive structures 1208a, 1208b, 1208c, 246a, 246b, and/or 246c may include a combination of conductive structures that extend primarily horizontally in the interconnect layer 1204 or the interconnect layer 240 (e.g., trenches, conductive lines) and that are interconnected by interconnect structures (e.g., vias) that extend primarily vertically in the interconnect layer 1204 or the interconnect layer 240.

As indicated above, FIGS. 12A-12C are provided as an example. Other examples may differ from what is described with regard to FIGS. 12A-12C.

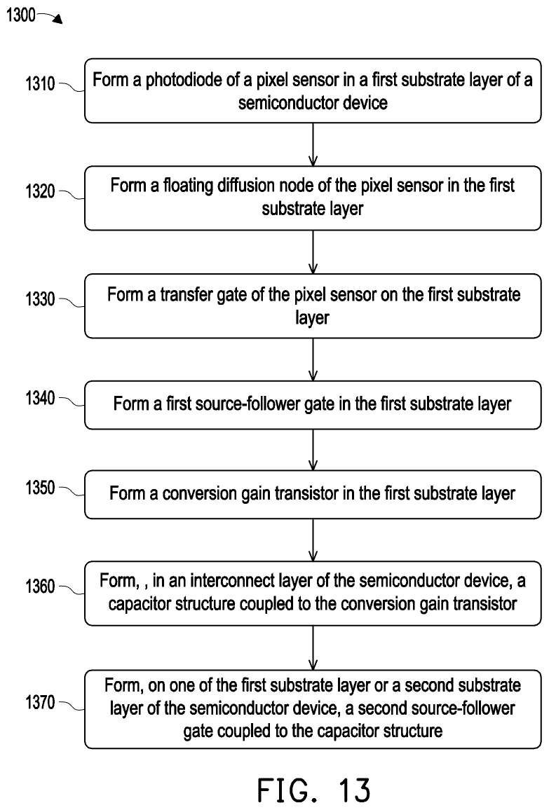

FIG. 13 is a flowchart of an example process 1300 associated with forming a semiconductor device. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming a photodiode of a pixel sensor in a first substrate layer of a semiconductor device (block 1310). For example, one or more semiconductor processing tools may be used to form a photodiode (e.g., photodiode 106) of a pixel sensor (e.g., pixel sensor 100) in a first substrate layer (e.g., substrate layer 218) of a semiconductor device (e.g., semiconductor device 200, 700, 800, 1200), as described herein.

As further shown in FIG. 13, process 1300 may include forming a floating diffusion node of the pixel sensor in the first substrate layer (block 1320). For example, one or more semiconductor processing tools may be used to form a floating diffusion node (e.g., floating diffusion node 110) of the pixel sensor in the first substrate layer, as described herein.

As further shown in FIG. 13, process 1300 may include forming a transfer gate of the pixel sensor on the first substrate layer (block 1330). For example, one or more semiconductor processing tools may be used to form a transfer gate (e.g., transfer gate 108) of the pixel sensor on the first substrate layer, as described herein.

As further shown in FIG. 13, process 1300 may include forming a first source-follower gate in the first substrate layer (block 1340). For example, one or more semiconductor processing tools may be used to form a first source-follower gate (e.g., a first source-follower gate 116) in the first substrate layer, as described herein. In some implementations, the first source-follower gate is coupled to the floating diffusion node.

As further shown in FIG. 13, process 1300 may include forming a conversion gain transistor in the first substrate layer (block 1350). For example, one or more semiconductor processing tools may be used to form a conversion gain transistor (e.g., first conversion gain transistor 124) in the first substrate layer, as described herein. In some implementations, the conversion gain transistor is coupled to the floating diffusion node.

As further shown in FIG. 13, process 1300 may include forming, in an interconnect layer of the semiconductor device, a capacitor structure coupled to the conversion gain transistor (block 1360). For example, one or more semiconductor processing tools may be used to form, in an interconnect layer (e.g., interconnect layer 240) of the semiconductor device, a capacitor structure (e.g., capacitor 128) coupled to the conversion gain transistor, as described herein.

As further shown in FIG. 13, process 1300 may include forming, on one of the first substrate layer or a second substrate layer of the semiconductor device, a second source-follower gate coupled to the capacitor structure (block 1370). For example, one or more semiconductor processing tools may be used to form, on one of the first substrate layer or a second substrate layer (e.g., substrate layer 242) of the semiconductor device, a second source-follower gate (e.g., second source-follower gate 134) coupled to the capacitor structure, as described herein.

Process 1300 may include additional implementations, such as any single implementation or any combination of implementations described below and/or in connection with one or more other processes described elsewhere herein.

In a first implementation, process 1300 includes forming, in one of the first substrate layer or the second substrate layer, an additional conversion gain transistor (e.g., second conversion gain transistor 132) coupled between the capacitor structure and the second source-follower gate.

In a second implementation, alone or in combination with the first implementation, a first source/drain terminal of the additional conversion gain transistor is coupled to the capacitor structure, and a second source/drain terminal of the additional conversion gain transistor is couped to the second source-follower gate.

In a third implementation, alone or in combination with one or more of the first and second implementations, the conversion gain transistor and the additional conversion gain transistor are coupled to the capacitor structure in parallel.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

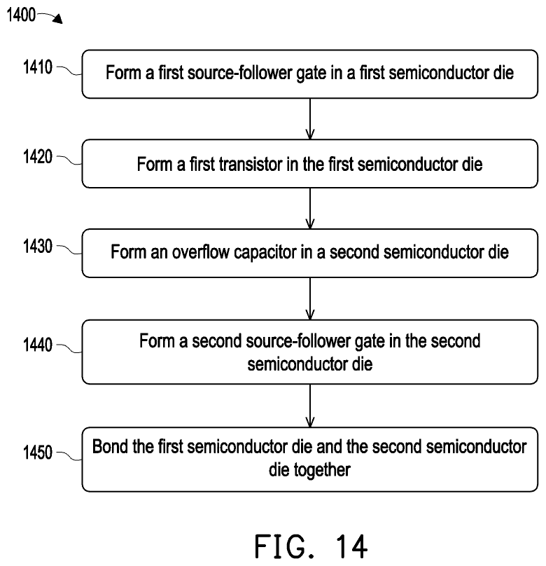

FIG. 14 is a flowchart of an example process 1400 associated with forming a semiconductor device. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming a first source-follower gate in a first semiconductor die (block 1410). For example, one or more semiconductor processing tools may be used to form a first source-follower gate (e.g., first source-follower gate 116) in a first semiconductor die (e.g., semiconductor die 202, 1202), as described herein. In some implementations, the first source-follower gate is coupled to a floating diffusion node (110) of a pixel sensor.

As further shown in FIG. 14, process 1400 may include forming a first transistor in the first semiconductor die (block 1420). For example, one or more semiconductor processing tools may be used to form a first transistor (e.g., first conversion gain transistor 124) in the first semiconductor die, as described herein. In some implementations, the first transistor is coupled to the floating diffusion node.

As further shown in FIG. 14, process 1400 may include forming an overflow capacitor in a second semiconductor die (block 1430). For example, one or more semiconductor processing tools may be used to form an overflow capacitor (e.g., capacitor 128) in a second semiconductor die (e.g., semiconductor die 204), as described herein. In some implementations, the overflow capacitor is coupled to the first transistor.

As further shown in FIG. 14, process 1400 may include forming a second source-follower gate in the second semiconductor die (block 1440). For example, one or more semiconductor processing tools may be used to form a second source-follower gate (e.g., second source-follower gate 134) in the second semiconductor die, as described herein. In some implementations, the second source-follower gate is coupled to the overflow capacitor through a second transistor (e.g., second conversion gain transistor 132).

As further shown in FIG. 14, process 1400 may include bonding the first semiconductor die and the second semiconductor die together (block 1450). For example, one or more semiconductor processing tools may be used to bond the first semiconductor die and the second semiconductor die together, as described herein.

Process 1400 may include additional implementations, such as any single implementation or any combination of implementations described below and/or in connection with one or more other processes described elsewhere herein.

In a first implementation, the second transistor is formed in the second semiconductor die.

In a second implementation, alone or in combination with the first implementation, process 1400 includes forming a photodiode (e.g. photodiode 106) of the pixel sensor in a substrate layer (e.g., substrate layer 218) of a third semiconductor die (e.g., semiconductor die 202), forming the floating diffusion node of the pixel sensor in the substrate layer, and forming a transfer gate (e.g. transfer gate 108) of the pixel sensor on the substrate layer.

In a third implementation, alone or in combination with one or more of the first and second implementations, process 1400 includes bonding the first semiconductor die and the third semiconductor die together.

In a fourth implementation, alone or in combination with one or more of the first through third implementations, process 1400 includes bonding the second semiconductor die to a third semiconductor die (e.g., semiconductor die 802), where the third semiconductor die includes at least one of an ISP die or an ASIC die.

In a fifth implementation, alone or in combination with one or more of the first through fourth implementations, process 1400 includes coupling a first source/drain terminal of the first transistor to the floating diffusion node, coupling a second source/drain terminal of the first transistor to the overflow capacitor, coupling a first source/drain terminal of the second transistor to the overflow capacitor, and coupling a second source/drain terminal of the second transistor to the second source-follower gate.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, a pixel sensor includes a first source-follower gate and a second-follower gate respectively connected to a photodiode and to an overflow capacitor such that the first source-follower gate may read a voltage of the photodiode, while the second source-follower gate simultaneously reads a voltage of the overflow capacitor. The arrangement including the first and second source-follower gates permits the photodiode and overflow capacitor voltages to be read at the same time, so that the time to read the photodiode and overflow capacitor voltages (e.g., read-out speed) is equal to the time during which the photodiode and overflow capacitor voltages are simultaneously read. The simultaneous reading of photodiode and overflow capacitor voltages increases an image sensor device frame rate in comparison to when the photodiode and overflow capacitor voltages are read in sequence, thereby increasing the rate at which an image sensor device captures images, and improving image sensor device performance.

As described in greater detail above, some implementations described herein provide a semiconductor device. The semiconductor device includes a photodiode in a substrate layer of the semiconductor device. The semiconductor device includes a transfer gate coupled to the photodiode. The semiconductor device includes a floating diffusion node coupled to the transfer gate. The semiconductor device includes a first source-follower gate coupled to the floating diffusion node. The semiconductor device includes a transistor coupled to the floating diffusion node. The semiconductor device includes a capacitor structure coupled to the transistor. The semiconductor device includes a second source-follower gate coupled to the capacitor structure.

As described in greater detail above, some implementations described herein provide a method. The method includes forming a photodiode of a pixel sensor in a first substrate layer of a semiconductor device. The method includes forming a floating diffusion node of the pixel sensor in the first substrate layer. The method includes forming a transfer gate of the pixel sensor on the first substrate layer. The method includes forming a first source-follower gate in the first substrate layer, where the first source-follower gate is coupled to the floating diffusion node. The method includes forming a conversion gain transistor in the first substrate layer, where the conversion gain transistor is coupled to the floating diffusion node. The method includes forming, in an interconnect layer of the semiconductor device, a capacitor structure coupled to the conversion gain transistor. The method includes forming, on one of the first substrate layer or a second substrate layer of the semiconductor device, a second source-follower gate coupled to the capacitor structure.

As described in greater detail above, some implementations described herein provide a method. The method includes forming a first source-follower gate in a first semiconductor die, where the first source-follower gate is coupled to a floating diffusion node of a pixel sensor. The method includes forming a first transistor in the first semiconductor die, where the first transistor is coupled to the floating diffusion node. The method includes forming an overflow capacitor in a second semiconductor die, where the overflow capacitor is coupled to the first transistor. The method includes forming a second source-follower gate in the second semiconductor die, where the second source-follower gate is coupled to the overflow capacitor through a second transistor. The method includes bonding the first semiconductor die and the second semiconductor die together.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a photodiode in a substrate layer of the semiconductor device;
a transfer gate coupled to the photodiode;
a floating diffusion node coupled to the transfer gate;
a first source-follower gate coupled to the floating diffusion node;
a transistor coupled to the floating diffusion node;
a capacitor structure coupled to the transistor; and
a second source-follower gate coupled to the capacitor structure.

2. The semiconductor device of claim 1, further comprising an additional transistor coupled between the capacitor structure and the second source-follower gate.

3. The semiconductor device of claim 1, further comprising:
a first row-select gate coupled to the first source-follower gate; and
a second row-select gate coupled to the second source-follower gate.

4. The semiconductor device of claim 1, wherein the first source-follower gate and the second source-follower gate are on the same semiconductor die.

5. The semiconductor device of claim 1, wherein the first source-follower gate is on a first semiconductor die and the second source-follower gate is on a second semiconductor die.

6. The semiconductor device of claim 5, wherein the capacitor structure is on the second semiconductor die.

7. The semiconductor device of claim 6, wherein the second semiconductor die comprises at least one of an image sensor processing (ISP) die or an application-specific integrated circuit (ASIC) die.

8. The semiconductor device of claim 5, further comprising an additional transistor coupled between the capacitor structure and the second source-follower gate,
wherein the transistor is on the first semiconductor die, and
wherein the additional transistor is on the second semiconductor die.

9. The semiconductor device of claim 5, wherein the photodiode is on the first semiconductor die.

10. The semiconductor device of claim 5, wherein the photodiode is on a third semiconductor die.

11. A method, comprising:
forming a photodiode of a pixel sensor in a first substrate layer of a semiconductor device;
forming a floating diffusion node of the pixel sensor in the first substrate layer;
forming a transfer gate of the pixel sensor on the first substrate layer;
forming a first source-follower gate in the first substrate layer,
wherein the first source-follower gate is coupled to the floating diffusion node;
forming a conversion gain transistor in the first substrate layer,
wherein the conversion gain transistor is coupled to the floating diffusion node;
forming, in an interconnect layer of the semiconductor device, a capacitor structure coupled to the conversion gain transistor; and
forming, on one of the first substrate layer or a second substrate layer of the semiconductor device, a second source-follower gate coupled to the capacitor structure.

12. The method of claim 11, further comprising forming, in one of the first substrate layer or the second substrate layer, an additional conversion gain transistor coupled between the capacitor structure and the second source-follower gate.

13. The method of claim 12, wherein a first source/drain terminal of the additional conversion gain transistor is coupled to the capacitor structure, and
wherein a second source/drain terminal of the additional conversion gain transistor is couped to the second source-follower gate.

14. The method of claim 12, wherein the conversion gain transistor and the additional conversion gain transistor are coupled to the capacitor structure in parallel.

15. A method, comprising:
forming a first source-follower gate in a first semiconductor die,
wherein the first source-follower gate is coupled to a floating diffusion node of a pixel sensor;
forming a first transistor in the first semiconductor die,
wherein the first transistor is coupled to the floating diffusion node;
forming an overflow capacitor in a second semiconductor die,
wherein the overflow capacitor is coupled to the first transistor;
forming a second source-follower gate in the second semiconductor die,
wherein the second source-follower gate is coupled to the overflow capacitor through a second transistor; and
bonding the first semiconductor die and the second semiconductor die together.

16. The method of claim 15, wherein the second transistor is formed in the second semiconductor die.

17. The method of claim 15, further comprising:
forming a photodiode of the pixel sensor in a substrate layer of a third semiconductor die;
forming the floating diffusion node of the pixel sensor in the substrate layer; and
forming a transfer gate of the pixel sensor on the substrate layer.

18. The method of claim 17, further comprising bonding the first semiconductor die and the third semiconductor die together.

19. The method of claim 15, further comprising bonding the second semiconductor die to a third semiconductor die,
wherein the third semiconductor die comprises at least one of an image sensor processing (ISP) die or an application-specific integrated circuit (ASIC) die.

20. The method of claim 15, further comprising:
coupling a first source/drain terminal of the first transistor to the floating diffusion node;
coupling a second source/drain terminal of the first transistor to the overflow capacitor;
coupling a first source/drain terminal of the second transistor to the overflow capacitor; and
coupling a second source/drain terminal of the second transistor to the second source-follower gate.
